(19) United States
(12) Patent Application Publication
(10) Pub. No.: US 2024/0186399 A1
(43) Pub. Date: Jun. 6, 2024

(54) SUPERLATTICE, FERROIC ORDER THIN FILMS FOR USE AS HIGH/NEGATIVE-K DIELECTRIC

(71) Applicant: The Regents of the University of California, Oakland, CA (US)

(72) Inventors: Sayeef Salahuddin, Walnut Creek, CA (US); Suraj Singh Cheema, Berkeley, CA (US); Nirmaan Shanker, Berkeley, CA (US); Cheng-Hsiang Hsu, Berkeley, CA (US); Daewoong Kwon, Seoul (KR)

(21) Appl. No.: 18/553,602

(22) PCT Filed: Apr. 5, 2022
(86) PCT No.: PCT/US2022/023433

§ 371 Date: Oct. 2, 2023

Related U.S. Application Data
(60) Provisional application No. 63/170,826, filed on Apr. 5, 2021.

(51) Int. Cl. H01L 29/51; H01L 21/02; H01L 29/40

(52) U.S. Cl. CPC H01L 29/513; H01L 21/02181; H01L 21/02189; H01L 21/0228; H01L 29/401; H01L 29/517

(57) ABSTRACT

Disclosed are HfO₂—ZrO₂ superlattice heterostructures such as a gate stack (24), stabilized with mixed ferroelectric-antiferroelectric order. directly integrated onto silicon (Si) transistors and scaled down to ˜20 Å. the same gate oxide thickness required for high-performance transistors. The overall equivalent oxide thickness in metal-oxide-semiconductor capacitors is ˜6.5 Å effective SiO₂ thickness, which is even smaller than the interfacial SiO₂ thickness (8.0-8.5 Å) itself. and the resulting large capacitance cannot be achieved in conventional HfO₂-based high-κ dielectric gate stacks without scavenging the interfacial SiO₂. which has adverse effects on the electron transport and gate leakage current. Accordingly. the disclosed gate stacks (24), which do not require such scavenging. provide substantially lower leakage current and no mobility degradation and demonstrate that HfO₂—ZrO₂ multilayers with competing ferroelectric-antiferroelectric order, stabilized in the sub-2 nm thickness regime, provide a path towards advanced gate oxide stacks in electronic devices beyond the conventional HfO₂-based high-κ dielectrics.

### RELATED APPLICATIONS

This application claims the benefit of U.S. provisional patent application Ser. No. 63/170,826, filed Apr. 5, 2021, the disclosure of which is hereby incorporated herein by reference in its entirety.

### GOVERNMENT SUPPORT

This invention was made with government support under Grant Number FA8650-19-2-7933 awarded by the Office of Naval Research. The government has certain rights in the invention.

### FIELD OF THE DISCLOSURE

The present disclosure relates to semiconductor devices and in particular to semiconductor devices that comprise superlattice heterostructures.

### BACKGROUND

With the scaling of lateral dimensions in advanced transistors, an increased gate capacitance is desirable both to retain the control of the gate electrode over the channel and to reduce the operating voltage. This need has led to the adoption of high-κ dielectric hafnium oxide (HfO₂) in the gate stack, which remains as the material of choice to date. Moreover, with the two-dimensional scaling of silicon field-effect transistors reaching fundamental limits, new functional improvements to transistors, as well as novel computing paradigms and vertical device integration at the architecture level, are currently under intense study. Gate oxides play a critical role in this endeavor, as gate oxides are a common performance booster for all devices, including silicon, new channel materials with potential for higher performance, and even materials suitable for three-dimensional integrated transistors. Indeed, the gate oxide transition from silicon dioxide (SiO₂) to high-κ dielectric (DE) is considered a paradigm shift in computing technology. In this context, ferroelectric oxides offer new functionalities considered promising for energy-efficient efficient electronics. The advent of atomic layer deposition (ALD)-grown ferroelectric-doped HfO₂ has overcome much of the material compatibility issues that plague traditional perovskite-based ferroelectric materials. In addition, considering ferroic order persists down to a thickness of 1 nm in this system allows for integration of these oxides in the most aggressively scaled devices in which the state-of-the-art high-κ oxide thickness is less than 2 nm.

In an advanced silicon transistor, the gate oxide is a combination of two distinct layers. The first is an interfacial SiO₂ formed with a self-limiting process, resulting in ˜8.0-8.5 Å thickness. The next is the high-κ (HK) dielectric HfO₂ layer that is typically ˜2 nm in thickness. Higher capacitance of this series combination is desirable to suppress short channel effects. The capacitance is conventionally represented by effective oxide thickness (EOT), EOT=t_{SiO}_{₂}+t_{HK}/(∈_{HK}/∈_{SiO}_{₂}), where lower EOT represents higher capacitance. Therefore, the EOT minimum value is limited by the interfacial SiO₂ thickness. Indeed, even integrating HfO₂ as the high-κ layer, the EOT is typically ˜9 Å. To go below this value, the semiconductor industry has implemented sophisticated scavenging techniques to reduce the SiO₂ thickness after the full gate stack is formed. Although this technique is very effective in scaling EOT, the thinner SiO₂ results in undesirable leakage current and mobility degradation. Thus, what is needed is a new gate structure that provides the desired higher capacitance while limiting undesirable leakage current and mobility degradation.

### SUMMARY

With the scaling of lateral dimensions in advanced transistors, an increased gate capacitance is desirable both to retain the control of the gate electrode over the channel and to reduce the operating voltage. This need has led to the adoption of high-κ dielectric hafnium oxide (HfO₂) in the gate stack, which remains as the material of choice to date. The present disclosure relates to HfO₂—ZrO₂ (zirconium oxide) superlattice heterostructures as a gate stack, stabilized with mixed ferroelectric-antiferroelectric order, directly integrated onto silicon (Si) transistors and scaled down to ˜20 Å, the same gate oxide thickness required for high-performance transistors. The overall equivalent oxide thickness in metal-oxide-semiconductor capacitors is ˜6.5 Å effective SiO₂ thickness, which is, counterintuitively, even smaller than the interfacial SiO₂ thickness (8.0-8.5 Å) itself. Such a low effective oxide thickness and the resulting large capacitance cannot be achieved in conventional HfO₂-based high-κ dielectric gate stacks without scavenging the interfacial SiO₂, which has adverse effects on the electron transport and gate leakage current. Accordingly, the gate stacks according to the present disclosure, which do not require such scavenging, provide substantially lower leakage current and no mobility degradation. The present disclosure demonstrates that HfO₂—ZrO₂ multilayers with competing ferroelectric-antiferroelectric order, stabilized in the sub-2 nm thickness regime, provide a path towards advanced gate oxide stacks in electronic devices beyond the conventional HfO₂-based high-κ dielectrics.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1A shows the phenomeno-logical model of negative capacitance in a mixed ferroic system, with Landau free energy landscapes for a ferroelectric (FE), antiferroelectric (AFE), and mixed FE-AFE system.

FIG. 1B shows engineering of ferroic phase competition in the HfO₂—ZrO₂ fluorite-structure system.

FIG. 1C depicts thin films of HfO₂—ZrO₂ that are grown using atomic layer deposition (ALD) in which the nanolaminate periodicity is dictated by the sequence of Hf:Zr (4:12) ALD cycles before the Hf—Zr superstructure is repeated various times.

FIG. 1D shows the underlying mixed ferroic order in these HfO₂—ZrO₂ heterostructures as established by high-resolution TEM.

FIG. 1E shows synchrotron in-plane grazing incidence diffraction demonstrating the presence of both the AFE T-phase (101) and FE O-phase (111) reflections the d-lattice spacings of which are consistent with those extracted from TEM.

FIG. 2A shows metal-insulator-metal (MIM) capacitance-voltage (C-V) hysteresis loops for a mixed FE-AFE HfO₂—ZrO₂ multilayer demonstrating higher capacitance compared against its AFE (ZrO₂) and FE (Zr:HfO₂) counterparts of the same thickness.

FIG. 2B shows the inverse capacitance versus thickness of the MIM HfO₂—ZrO₂ multilayers up to five superlattice repeats (10 nm), with an extracted permittivity of 52, which is extremely large for HfO₂-based oxides.

FIG. 2C shows MIM C-V hysteresis loops for HfO₂—ZrO₂ multilayers of the same periodicity demonstrating an evolution from mixed-ferroic to FE-like hysteresis upon cooling slightly below room temperature.

FIG. 2D shows metal oxide semiconductor (MOS) accumulation C-V of HfO₂—ZrO₂—HfO₂ trilayer compared with AFE ZrO₂, FE Zr:HfO₂, and high-κ dielectric HfO₂, all of the same thickness (20 Å) , indicating mixed-ferroic behavior is optimal for enhancing capacitance rather than purely FE or AFE behavior.

FIG. 2E shows accumulation C-V of the HfO₂—ZrO₂—HfO₂ trilayer compared with bilayer and solid-solution films of the same thickness (ALD cycles) and composition (Hf:Zr cycles), with an inset showing a diagram of multilayer (Hf and Zr cations vertically separated) versus solid solution (Hf and Zr cations intermixed).

FIG. 2F shows accumulation C-V curves for a 2 nm HfO2—ZrO₂—HfO₂ trilayer grown on sub-nanometer SiO₂ fit to effective oxide thickness (EOT) simulations.

FIG. 3A shows HfO₂—ZrO₂ multilayer and Zr-rich Hf:ZrO₂ solid solution films.

FIG. 3B shows MOS accumulation C-V of the HfO₂—ZrO₂—HfO₂ trilayer (60% Zr) compared with solid solution films of the same thickness (2 nm) and composition (60% Zr).

FIG. 3C shows MIM C-V hysteresis loops of the HfO₂—ZrO₂ superlattice (60% Zr) compared with solid solution films of the same thickness (6 nm) and composition (60% Zr).

FIG. 4A shows leakage-effective oxide thickness (J_{G}-EOT) scaling of the multilayer gate stacks benchmarked against reported high-K metal gate (HKMG) literature.

FIG. 4B shows normalized mobility versus EOT scaling of the multilayer gate stacks benchmarked against reported HKMG literature.

FIG. 4C shows a graph showing gₘ versus gate voltage (V_{G}) for long-channel bulk transistors (L_{G}=1 μm).

FIG. 4D shows a transfer characteristic of a typical transistor.

FIG. 4E shows an output characteristic of a typical transistor.

FIG. 4F shows device de-embedded and extrinsic transconductance.

FIG. 5 is a cross-sectional view of an exemplary embodiment of a semiconductor device in the form of an advanced transistor that is accordance with the present disclosure.

FIG. 6A shows the HfO₂—ZrO₂ multilayer structure on SiO₂-buffered silicon.

FIG. 6B shows synchrotron X-ray-reflectometry (XRR) of thicker HfO₂—ZrO₂ heterostructures repeated with the same periodicity as the thinner trilayer structure.

FIG. 6C shows layer-resolved electron energy loss spectroscopy (EELS) of the 2 nm HfO₂—ZrO₂—HfO₂ trilayer, which again shows clear separation of HfO₂—ZrO₂ layers following the expected 4 Å-12 Å-4 Å HfO₂—ZrO₂—HfO₂ structure.

FIG. 6D illustrates angle-resolved X-ray photoelectron spectroscopy (XPS) of the 2 nm HfO₂—ZrO₂—HfO₂ trilayer and the extracted atomic composition.

FIG. 7A shows HfO₂—ZrO₂ multilayer and Hf: ZrO₂ solid solution films.

FIG. 7B shows a comparison of MOS capacitor accumulation C-V characteristics in HfO₂—ZrO₂ multilayers.

FIG. 7C is a diagram showing a comparison of mixed-ferroic behavior in low-temperature treated MIM HfO₂—ZrO₂ multilayers versus FE behavior in in the same multilayers annealed at high temperatures.

FIG. 8A illustrates in-plane synchrotron grazing-incidence diffraction (GID) of a bare HfO₂—ZrO₂—HfO₂ trilayer indexed to the tetragonal/orthorhombic phases.

FIG. 8B illustrates the two-dimensional reciprocal space map of a bare 2 nm HfO₂—ZrO₂—HfO₂ trilayer indexed to the tetragonal/orthorhombic phases by indexing integrated diffraction spectrum.

FIG. 8C illustrates synchrotron X-ray absorption spectroscopy (XAS) of a bare 2 nm HfO₂—ZrO₂—HfO₂ trilayer at the Hf M₃ (left) and Zr L_{3,2} edges.

FIG. 8D shows second harmonic generation (SHG) mapped across a bare 2 nm HfO₂—ZrO₂—HfO₂ trilayer.

FIG. 8E shows mixed ferroic order in HfO₂—ZrO₂ heterostructures is established by high-resolution TEM along with graphs of intensity versus distance.

FIG. 8F shows additional mixed ferroic order in HfO₂—ZrO₂ heterostructures is established by high-resolution TEM along with graphs of intensity versus distance. FIG. 9A is a graphic indicating transition from mixed tetragonal-orthorhombic phase to predominately orthorhombic structure as a function of temperature.

FIG. 9B shows crystal field splitting for fluorite-structure polymorphs; the symmetry-induced e-splitting provides a spectroscopic signature for the polar O-phase.

FIG. 9C shows hard and soft synchrotron X-ray spectroscopy measured at beamline 4-ID-D of the Advanced Photon Source.

FIG. 9D shows simulated oxygen K-edge XAS spectra for the respective O-phase and T-phase; the XAS provides spectroscopic signatures to distinguish between the O-phase and T-phase, which are difficult to resolve from GID.

FIG. 9E shows prototypical C-V behavior for mixed antiferroelectric-ferroelectric and ferroelectric films in MIM capacitor structures.

FIG. 9F shows temperature-dependent C-V for thicker HfO₂—ZrO₂ multilayers of the same periodicity demonstrating an evolution from mixed-ferroic to ferroelectric-like hysteresis upon cooling slightly below room temperature.

FIG. 10A illustrates zoomed-out and zoomed-in cross-sectional TEM images of HfO₂—ZrO₂ multilayer structure along with a graph of intensity versus position.

FIG. 10B shows C-V measurements of HfO₂ thickness series.

FIG. 10C shows Q-V measurements of HfO₂ thickness series.

FIG. 10D shows C-V measurements of Al₂O₃ thickness series.

FIG. 10E shows Q-V measurements of Al₂O₃ thickness series.

FIG. 10F shows the consistency in the SiL Q-V relation extracted from the C-V data from both the HfO₂ and Al₂O₃ thickness series.

FIG. 11A shows split C-V curves obtained for multilayer HfO₂—ZrO₂ gate stacks (repeated 1 and 3 times).

FIG. 11B shows I_{D}-V_{G} transfer characteristics for L_{G}=1 μm bulk transistors at V_{DS}=50 mV for multiple devices per sample.

FIG. 11C shows gₘ-V_{G} transfer characteristics for L_{G}=1 m bulk transistors at V_{DS}=50 mV for multiple devices per sample.

FIG. 11D shows a series resistance extraction from 1/Vₒᵥ method for Vₒᵥ=V_{gs}−Vₜ=0.3 V to 0.5 V for L_{G}=1 μm.

FIG. 11E shows extracted mobility as a function of inversion sheet charge density; the effective mobility was taken to be the average maximum mobility across all measured devices.

FIG. 11F shows a transfer I_{D}-V_{G} data set fit to a constant mobility model based on the extracted effectively mobility in FIG. 11E.

FIG. 11G shows a transfer gₘ data set fit to a constant mobility model based on the extracted effectively mobility in FIG. 11E.

FIG. 12A shows threshold voltage extraction by linear extrapolation for various channel lengths.

FIG. 12B shows source/drain series resistance extracted using the 1/Vₒᵥ method.

FIG. 12C shows source/drain series resistance extracted using the line resistance method.

FIG. 12D shows measured and extracted transconductance versus V_{G} for V_{DS}=0.9 V to 1.1 V, assuming Rₛ=R_{d}=250 Ω-μm for L_{G}=90 nm.

FIG. 12E shows measured (left) and extracted (right) output conductance versus V_{G} for V_{DS}=0.9 V to 1.1 V, assuming Rₛ=R_{d}=250 Ωμm for L_{G}=90 nm.

FIG. 13A is a diagram of a de-embedding procedure for extracting corrected admittance parameters by decoupling parasitic shunt capacitance and series resistance and inductance.

FIG. 13B depicts a small-signal model of the transistor of the present disclosure.

FIG. 13C shows de-embedded

$$\frac{R e [ {Y}_{21} ]}{2 π f}$$

as a function of squared frequency at different DC V_{GS} bias points extrapolated to the zero frequency limit to extract the RF gₘ.

FIG. 14A shows a metal oxide semiconductor of the 20 Å HfO₂—ZrO₂—HfO₂ mixed ferroic trilayer sample on lightly doped Si (10¹⁵ cm⁻³).

FIG. 14B shows accumulation C-V curves for the 2 nm HfO₂—ZrO₂—HfO₂ trilayer grown on sub-nanometer SiO₂ fit to effective oxide thickness (EOT) simulations.

FIG. 14C shows the applied voltage pulse, the measured current

response, and the integrated charge as a function of time for 2 nm HfO₂—ZrO₂—HfO₂ trilayer in MOS capacitors.

FIG. 14D shows the maximum charge, the residual charge, and their difference derived from the charge vs. time curve for each of the voltage pulses.

FIG. 14E shows the reversible charge of the MOS layer compared with the extracted charge of the Si charge layer plus SiO₂ interlayer (SiL) derived electrically.

FIG. 14F is a scatter plot of reported ferroelectric-dielectric systems demonstrating negative capacitance at the capacitor level via capacitance or charge enhancement.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

With the two-dimensional scaling of silicon field-effect transistors reaching fundamental limits, new functional improvements to transistors, as well as novel computing paradigms and vertical device integration at the architecture level, are currently under intense study. Gate oxides play a critical role in this endeavor, as gate oxides are a common performance booster for all devices, including silicon, new channel materials with potential for higher performance, and even materials suitable for three-dimensional integrated transistors. Indeed, the gate oxide transition from silicon dioxide (SiO₂) to high-κ dielectric (DE) is considered a paradigm shift in computing technology. In this context, ferroelectric oxides offer new functionalities considered promising for energy-efficient electronics. The advent of atomic layer deposition (ALD)-grown ferroelectric-doped hafnium oxide (HfO₂) has overcome much of the material compatibility issues that plague traditional perovskite-based ferroelectric materials. In addition, considering ferroic order persists down to a thickness of 1 nm in this system allows for integration of these oxides in the most aggressively scaled devices in which the state-of-the-art high-κ oxide thickness is less than 2 nm.

In an advanced silicon transistor, the gate oxide is a combination of two distinct layers. The first is an interfacial SiO₂ formed with a self-limiting process, resulting in ˜8.0-8.5 Å thickness. The next is the high-κ (HK) dielectric HfO₂ layer that is typically ˜2 nm in thickness. Higher capacitance of this series combination is desirable to suppress short channel effects. The capacitance is conventionally represented by effective oxide thickness (EOT), EOT=t_{SiO}_{₂}+t_{HK}/(∈_{HK}/∈_{SiO}_{₂}), where lower EOT represents higher capacitance. Therefore, the EOT minimum value is limited by the interfacial SiO₂ thickness. Indeed, even integrating HfO₂ as the high-κ layer, the EOT is typically ˜9 Å. To go below this value, the semiconductor industry has implemented sophisticated scavenging techniques to reduce the SiO₂ thickness after the full gate stack is formed. Although this technique is very effective in scaling EOT, the thinner SiO₂ results in undesirable leakage and mobility degradation.

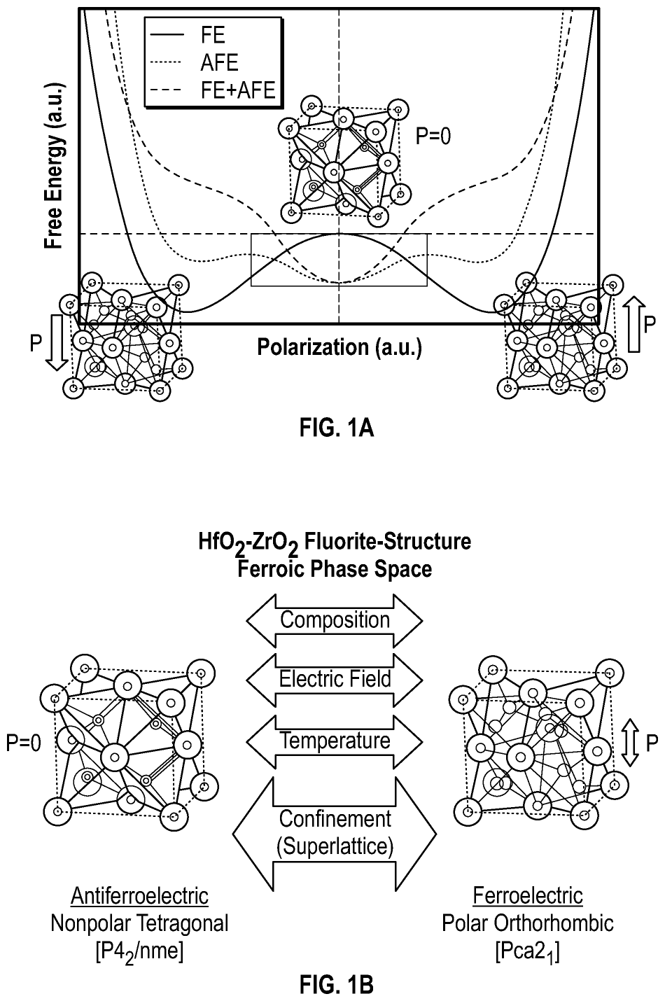

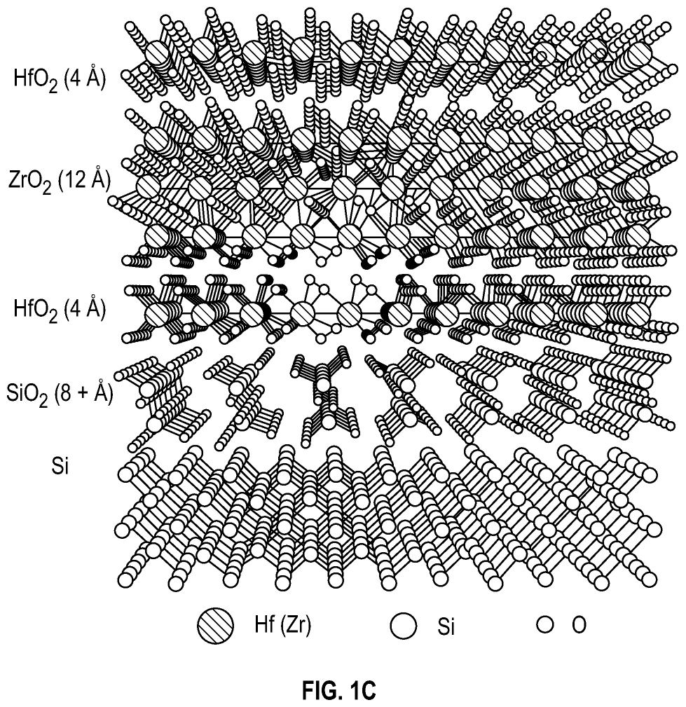

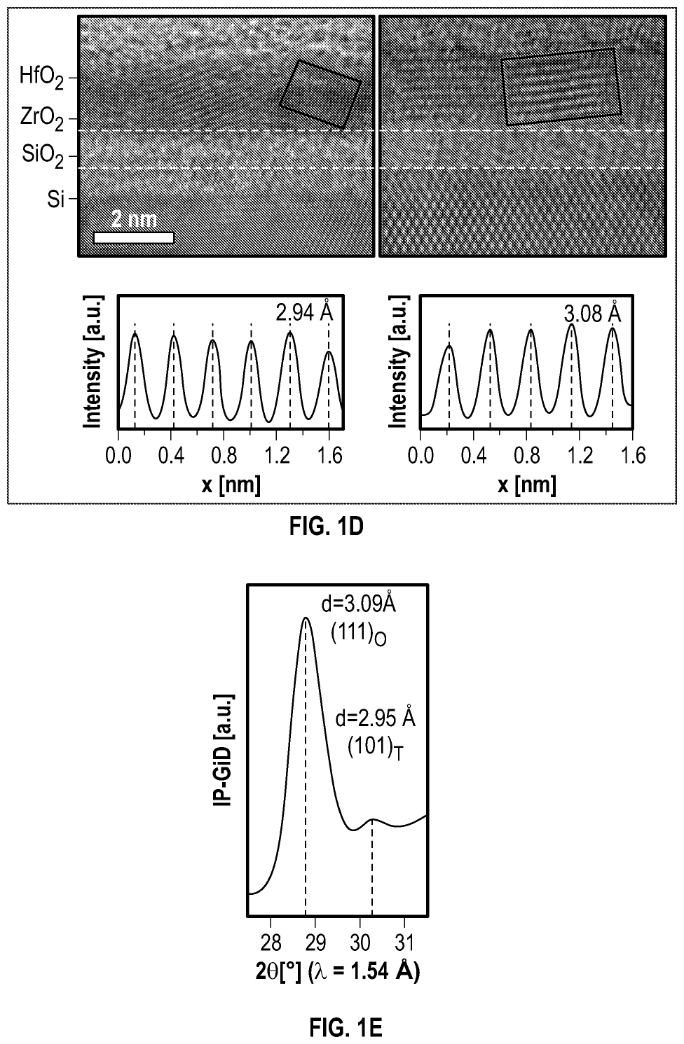

Disclosed is an ultrathin HfO₂—ZrO₂ (zirconium oxide) superlattice gate stack that exploits mixed ferroelectric-antiferroelectric (FE-AFE) order, as shown in FIGS. 1A and 1B. The films as disclosed demonstrate mixed ferroic order down to 2 nm thickness-the same thickness of high- oxide used in advanced transistors. Moreover, when integrated with silicon, the films show an overall EOT of <6.5 Å, despite the fact that both transmission electron microscopy (TEM) and electrical characterization reveal 8.0-8.5 Å interfacial SiO₂ thickness, as is typically expected. In at least some embodiments the oxide layer has an effective thickness between 5.5 Å and 6.5 Å. The larger capacitance than its constituent layers is a signature of the charge boost stemming from the negative capacitance effect, possible in materials with ferroic order. The EOT shows a clear dependence on the specific sequence and layering, underlying atomic-level control of the gate oxide behavior. The fact that sub-8 Å EOT is achieved without any interfacial SiO₂ scavenging results in substantially lower leakage current for the same EOT compared with benchmarks established by major semiconductor industries. In addition, no mobility degradation is observed as EOT is scaled with these HfO₂—ZrO₂ ferroic gate stacks. Furthermore, large ON current (>1 mA/μm) obtained in L_{G}=90 nm transistors indicate that there is no adverse effect on the carrier velocity. Therefore, ultrathin HfO₂—ZrO₂ multilayers exploiting ferroic order provide a new pathway toward energy-efficient gate stacks for advanced transistors.

FIGS. 1A to 1E illustrate the atomic-scale design of negative capacitance in ultrathin hafnium oxide-zirconium oxide (HfO₂—ZrO₂). FIG. 1A shows the phenomeno-logical model of negative capacitance in a mixed ferroic system, with Landau free energy landscapes for a ferroelectric, antiferroelectric, and mixed FE-AFE system. Mixed FE-AFE phase competition should suppress polarization and enhance electric susceptibility via proximity to a phase boundary, flatten the energy landscape, and provide for desirable traits for negative capacitance stabilization. The stable energy minimum of the composite free energy landscape, corresponding to the negative curvature regime of the ferroelectric energy landscape, is highlighted.

FIG. 1B shows engineering of ferroic phase competition in the HfO₂—ZrO₂ fluorite-structure system. Beyond the conventionally studied tuning parameters-composition, electric field, temperature-are introduced dimensional confinement via superlattice layering to tailor ferroic phase competition at the atomic-scale.

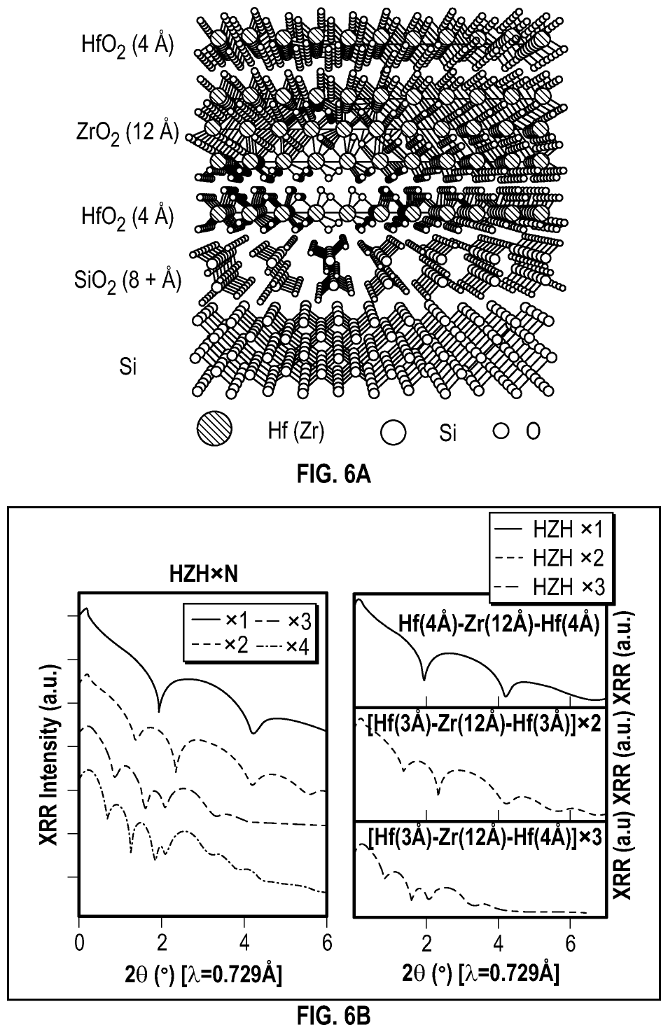

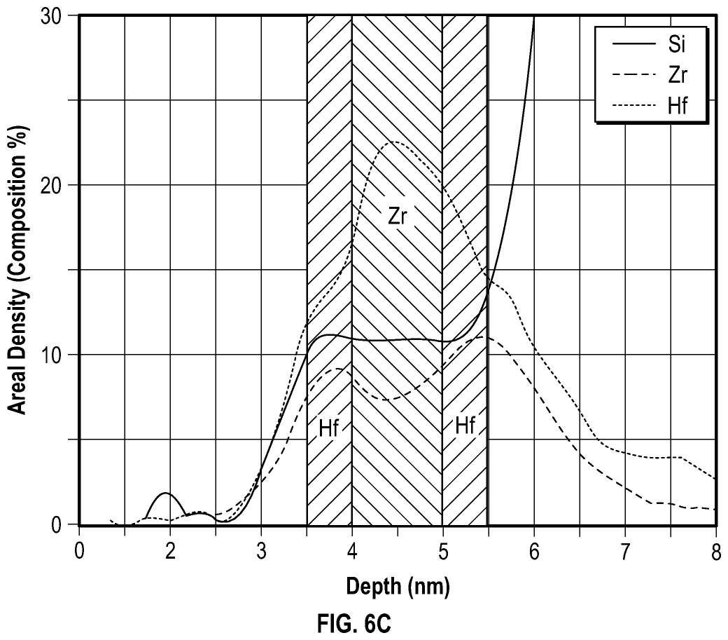

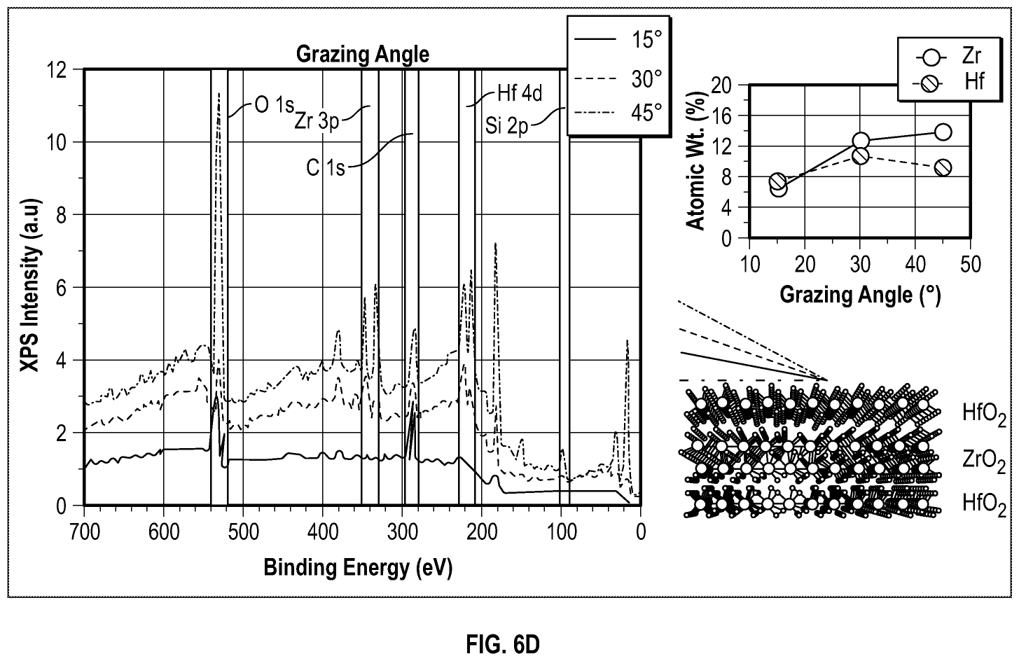

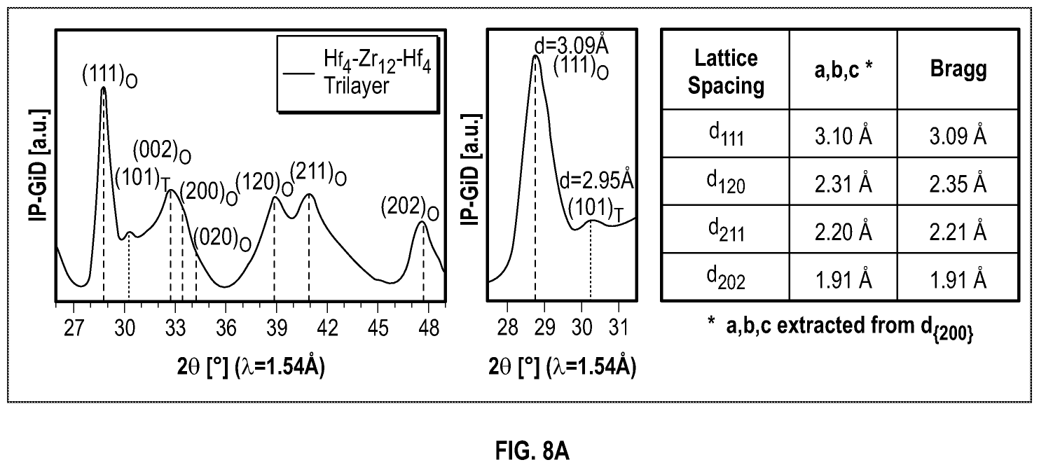

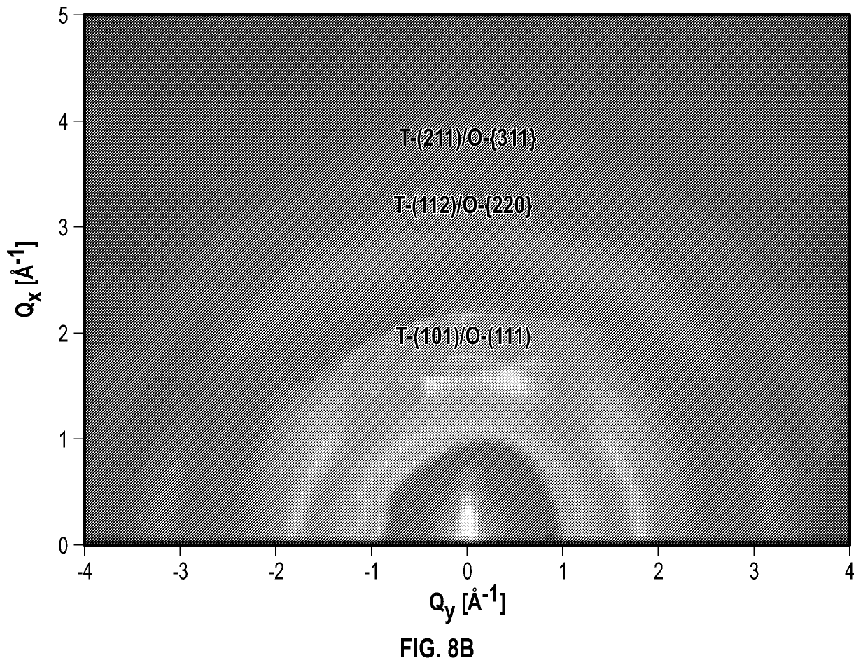

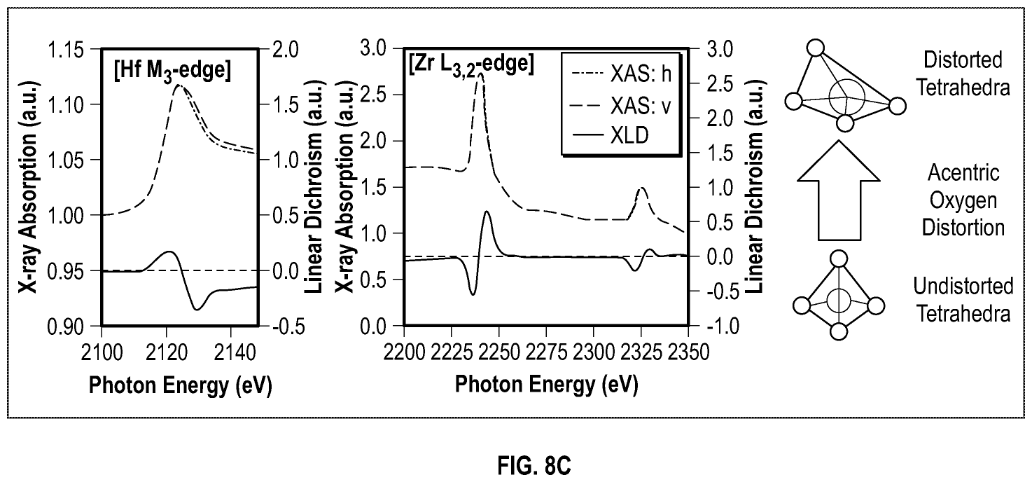

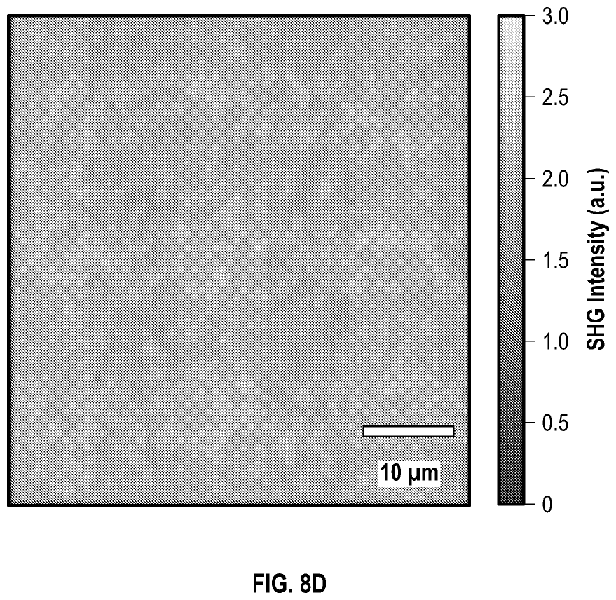

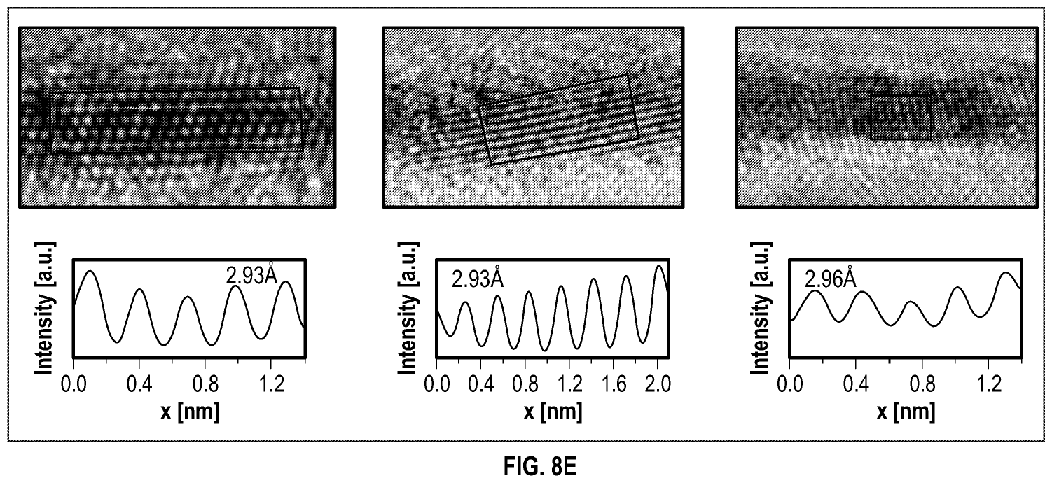

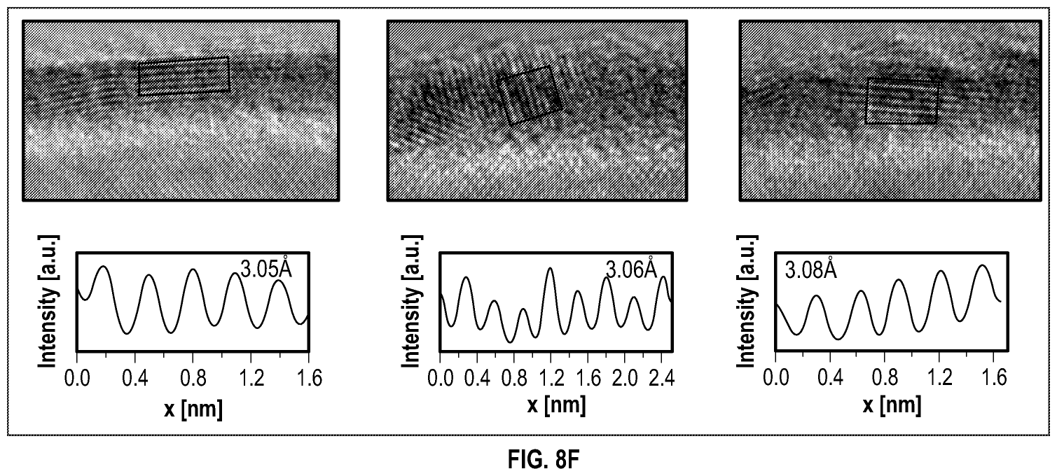

Thin films of HfO₂—ZrO₂ are grown using ALD in which the nanolaminate periodicity is dictated by the sequence of Hf:Zr (4:12) ALD cycles before the Hf—Zr superstructure is repeated various times (FIG. 1C). After top metal deposition, the entire gate stack undergoes a low-temperature post-metal anneal (200° C., 60 s, N₂), which does not interfere with the HfO₂—ZrO₂ multilayer structure, as various characterization techniques-synchrotron x-ray reflectivity (XRR), layer-resolved electron energy loss spectroscopy (EELS), and angle-resolved X-ray photoelectric spectroscopy (XPS)-confirm the expected Hf 4 Å to Zr 12 Å periodicity (see also FIGS. 6A to 6D). The underlying mixed ferroic order in these HfO₂—ZrO₂ heterostructures is established by high-resolution TEM (FIG. 1D; see also FIGS. 8E and 8F) and in-plane grazing incidence diffraction (FIG. 1E; see also FIGS. 8A and 8B). Both techniques indicate the presence of the tetragonal (P4₂/nmc, T-) and orthorhombic (Pca2₁, O-) phase, which correspond to antiferroelectric and ferroelectric order in fluorite-structure films, respectively. Synchrotron X-ray spectroscopy and optical spectroscopy further confirm the presence of inversion symmetry breaking in the 2 nm HfO₂—ZrO₂—HfO₂ superlattice heterostructure (see also FIGS. 8C and 8D).

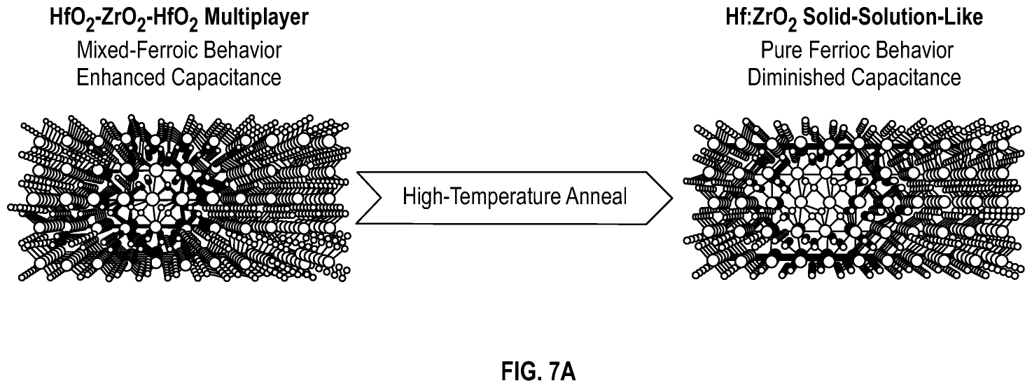

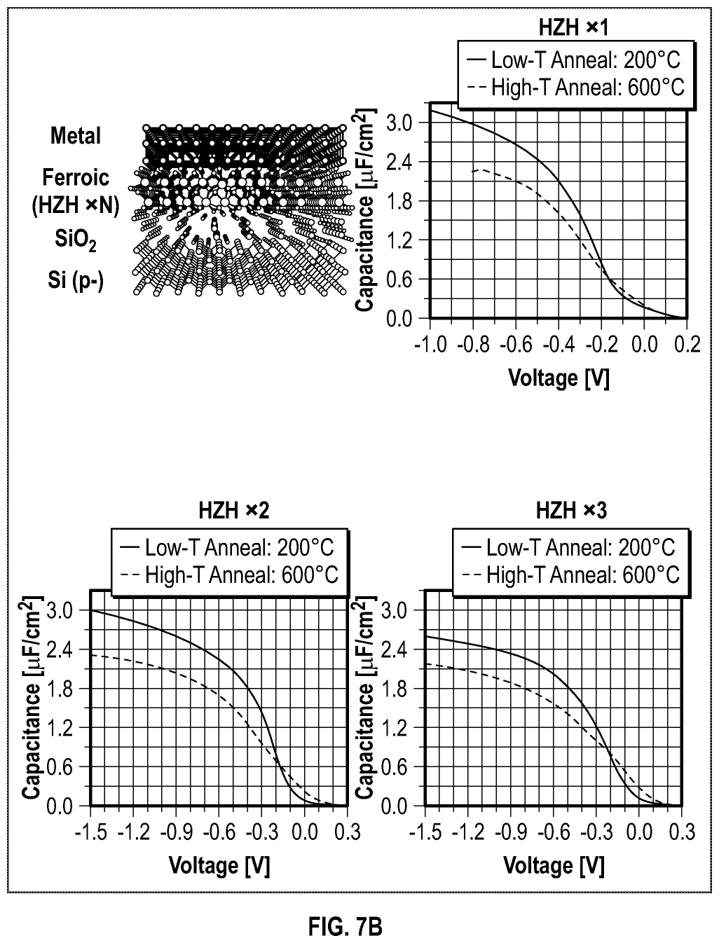

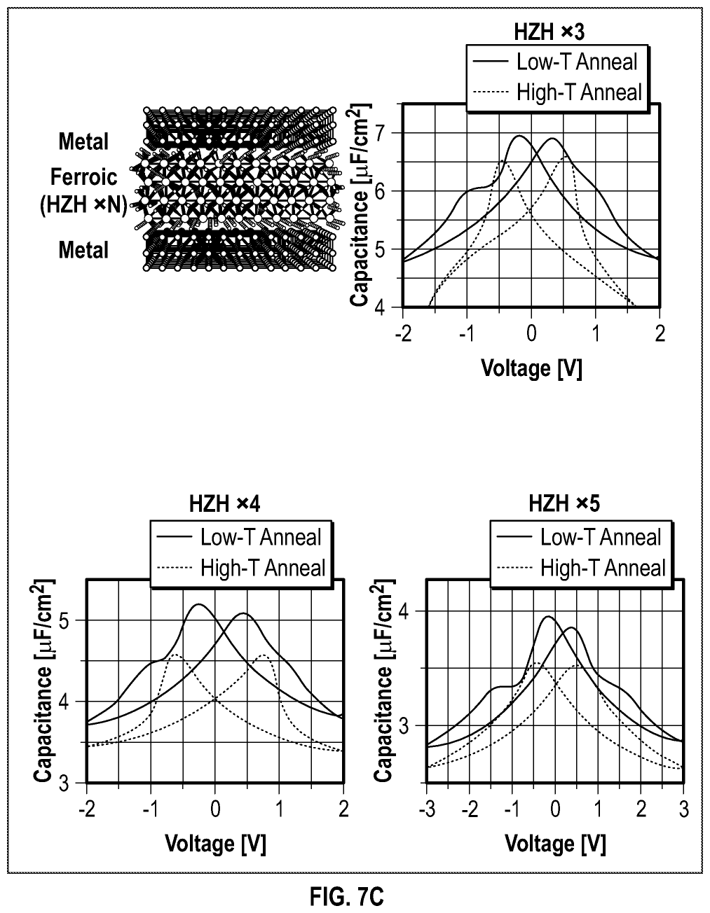

FIG. 1C shows the HfO₂—ZrO₂ fluorite-structure multilayer on silicon (Si), in which the heterostructures maintain distinct layers (i.e., not solid solution alloys) based on EELS, x-ray reflectivity (XRR), and depth-resolved XPS. The role of the layering on the underlying ferroic order and capacitance is studied by electrical measurements as a function of annealing temperature and HfO₂—ZrO₂ stacking structure (see also FIGS. 7A to 7C).

FIG. 1D shows a high-resolution transmission electron microscopy image of the atomic-scale HfO₂—ZrO₂—HfO₂ trilayer (top) and extracted d-lattice spacings (bottom) corresponding to the tetragonal (P4₂/nmc, left) and orthorhombic (Pca2₁, right) crystal structures corresponding the fluorite-structure AFE and FE phases, respectively.

FIG. 1E shows synchrotron in-plane grazing incidence diffraction demonstrating the presence of both the AFE T-phase (101) and FE O-phase (111) reflections the d-lattice spacings of which are consistent with those extracted from TEM. Detailed indexing to higher-order reflections for structural identification of the ferroic phases is provided by wide-angle synchrotron diffraction (see also FIG. 8A). Further evidence of inversion symmetry breaking is provided by second harmonic generation and synchrotron linear dichroism (see also FIGS. 8C and 8D).

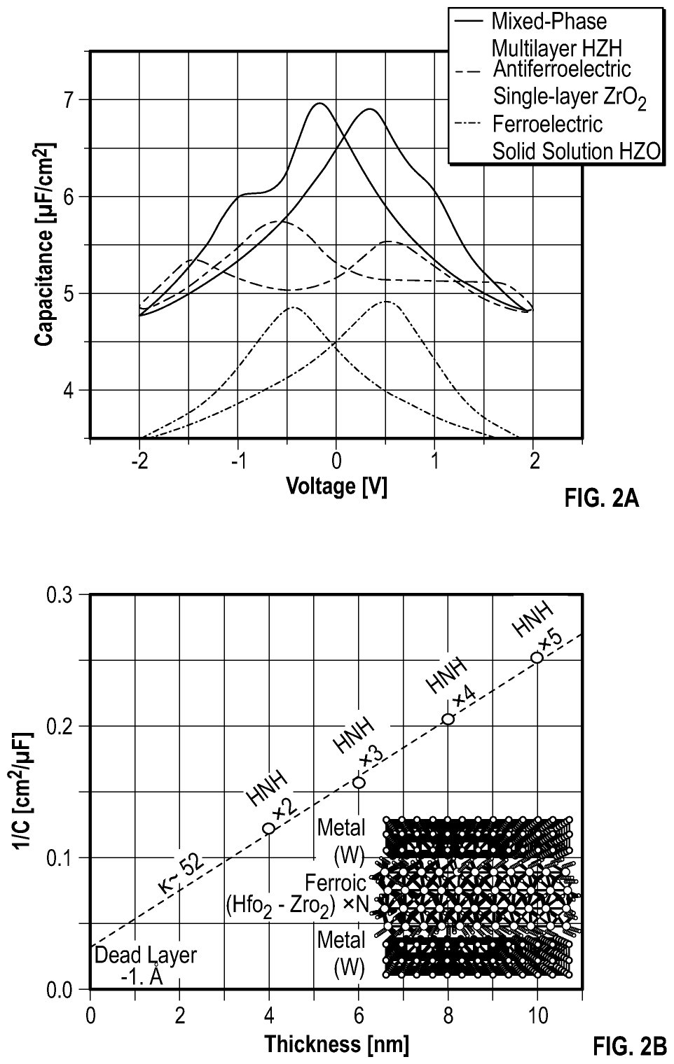

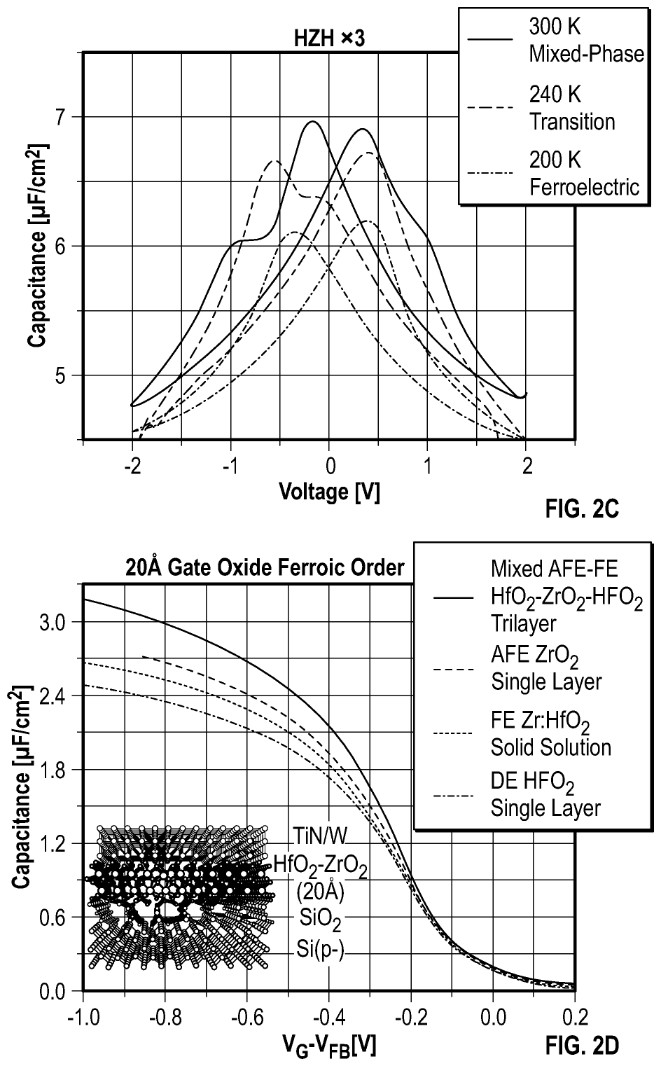

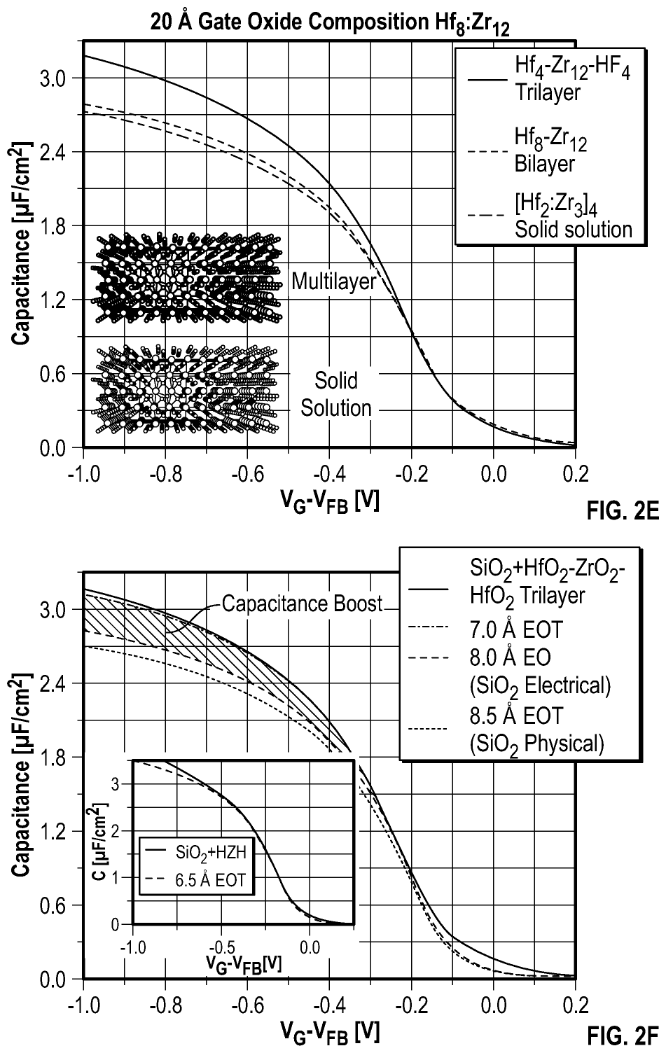

Mixed-ferroic atomic-scale HfO₂—ZrO₂ multilayers designed considering FE-AFE order can tune the free energy landscape in a similar manner to the FE-DE model systems originally studied for negative capacitance stabilization (FIG. 1A). From the energy landscape picture within a Landau formalism, the competition between the negative curvature (negative capacitance) of the FE and the positive curvature (positive capacitance) of the AFE can flatten the overall energy landscape, thereby substantially increasing the susceptibility. To confirm the higher susceptibility in the mixed AFE-FE system directly, capacitance-voltage (C-V) hysteresis loops were performed in metal-insulator-metal (MIM) capacitor structures on thicker films with the same superlattice periodicity (FIG. 2A). Besides features indicative of mixed FE-AFE order, the total capacitance for the superlattice is larger than both conventional AFE ZrO₂ and FE Zr: HfO₂ of the same thickness (FIG. 2A), demonstrating enhanced susceptibility. To quantify the permittivity, capacitance measurements were performed across the superlattice thickness series. These measurements yield an extracted permittivity of ˜52 (FIG. 2B), which is larger than both FE orthorhombic Zr:HfO₂ and AFE tetragonal ZrO₂ values.

FIGS. 2A to 2F illustrate enhanced capacitance in ultrathin HfO₂—ZrO₂ mixed-ferroic heterostructures. FIG. 2A shows MIM capacitance-voltage (C-V) hysteresis loops for a mixed FE-AFE HfO₂—ZrO₂ multilayer demonstrating higher capacitance compared against its AFE (ZrO₂) and FE (Zr:HfO₂) counterparts of the same thickness.

FIG. 2B shows the inverse capacitance versus thickness of the MIM HfO₂—ZrO₂ multilayers up to five superlattice repeats (10 nm), with an extracted permittivity of 52, which is extremely large for HfO₂-based oxides.

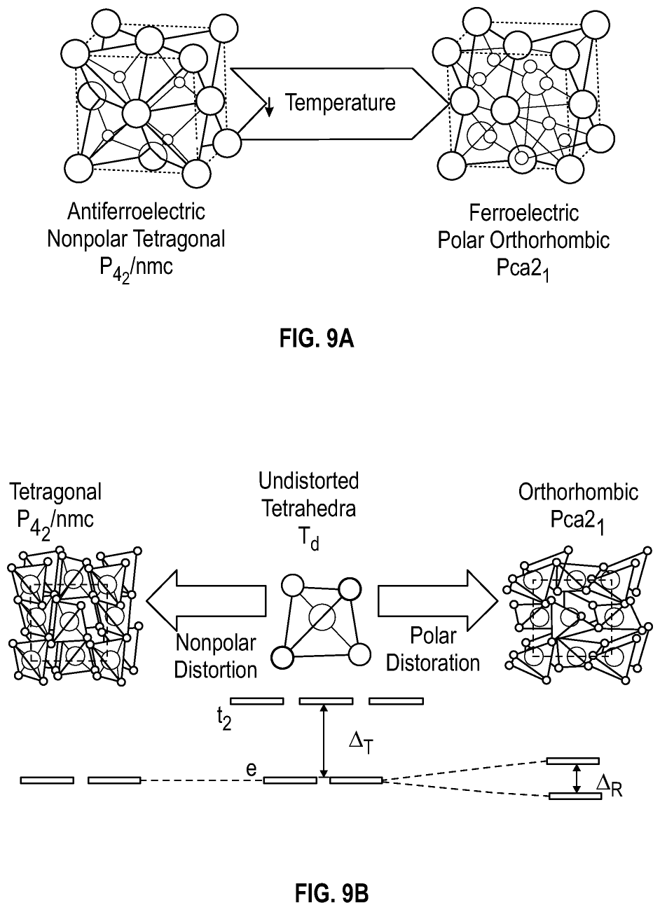

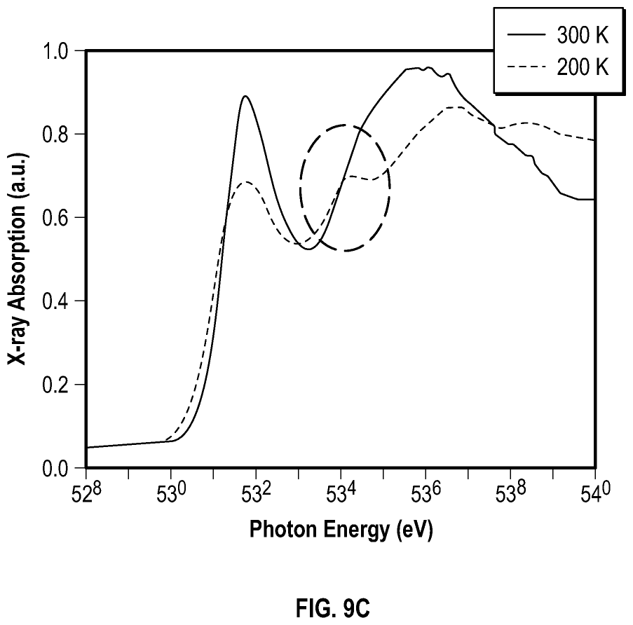

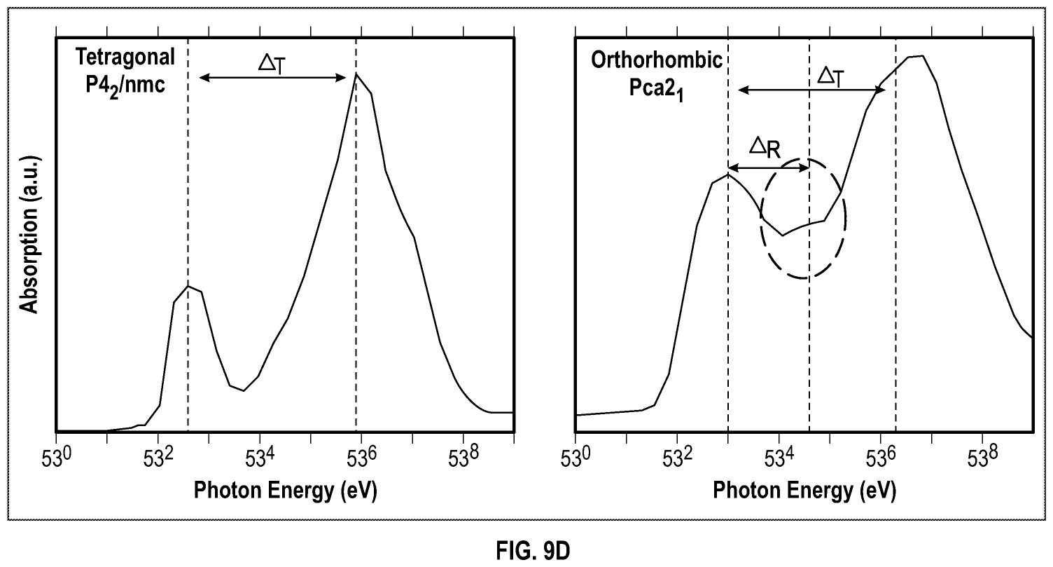

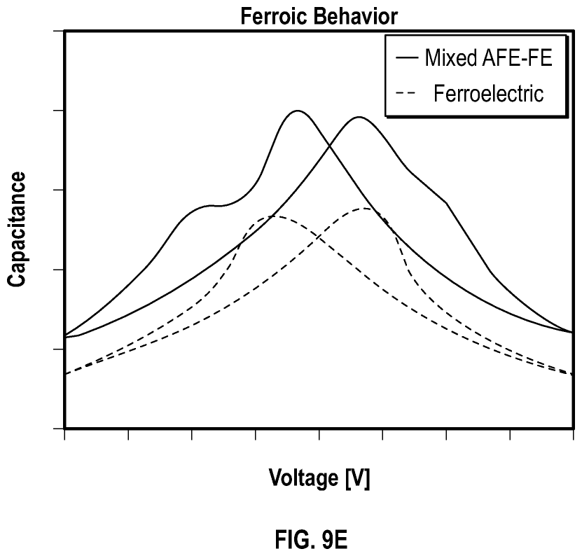

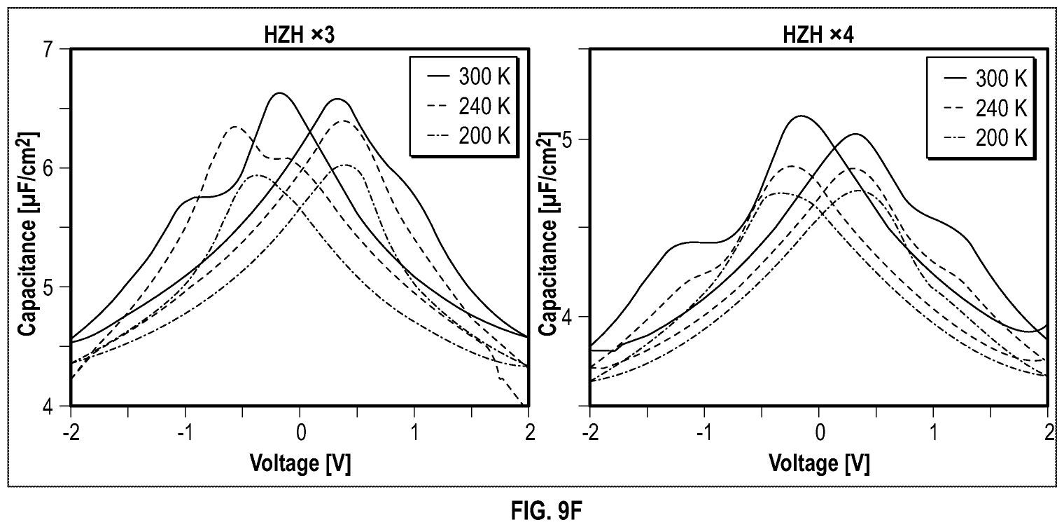

To further understand the ferroic evolution in these HfO₂—ZrO₂ superlattices, low temperature measurements were performed where enhanced FE phase stabilization is expected. Indeed, temperature-dependent C-V loops for thicker HfO₂—ZrO₂ multilayers demonstrate an evolution from mixed-ferroic to FE-like hysteresis upon cooling slightly below room temperature (˜240 K, FIG. 2C), consistent with temperature-dependent X-ray spectroscopy indicating transition from mixed tetragonal-orthorhombic phase to predominately orthorhombic structure at similar temperatures (see also FIGS. 9A to 9F). The capacitance decrease upon cooling as the system moves away from the highly susceptible mixed ferroic phase is consistent with previous work on negative capacitance in FE-DE systems, which establishes the energy landscape link between enhanced capacitance and susceptibility near phase transitions. Notably, the intertwined FE-AFE phases within the superlattice and resulting enhancement in susceptibility from the competition of FE and AFE phases is conceptually similar to negative stiffness composites of ferroelastics within a metal matrix, that is, the mechanical analog to negative capacitance.

FIG. 2C shows MIM C-V hysteresis loops for HfO₂—ZrO₂ multilayers of the same periodicity demonstrating an evolution from mixed-ferroic to FE-like hysteresis upon cooling slightly below room temperature. The proximity to the temperature-dependent phase transition (see also FIGS. 9A to 9F) suggests the HfO₂—ZrO₂ heterostructures lies near the maximum electric susceptibility position, ideal for negative capacitance stabilization.

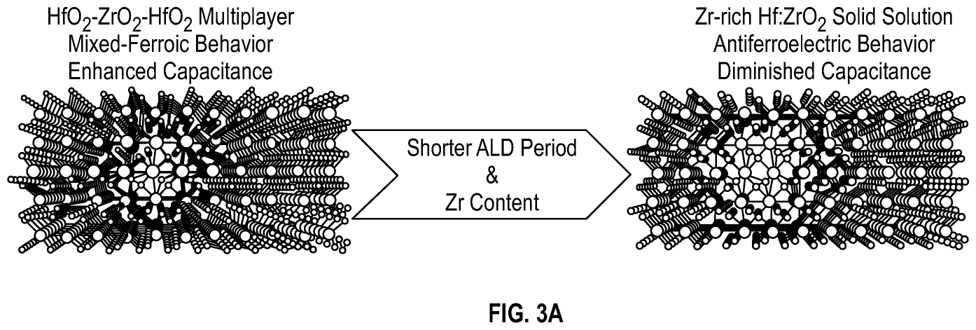

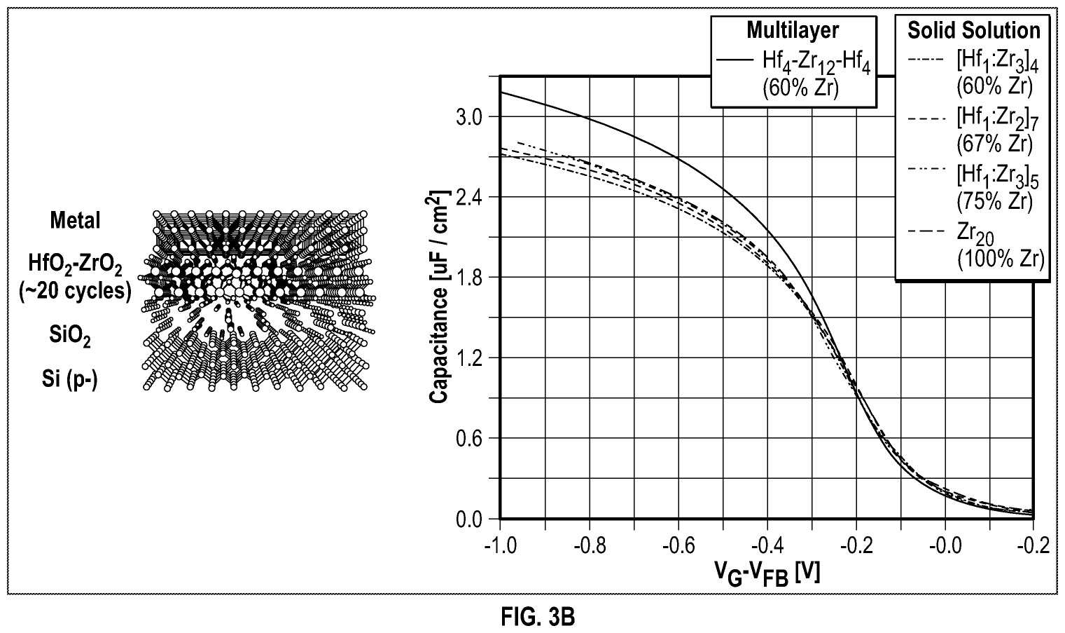

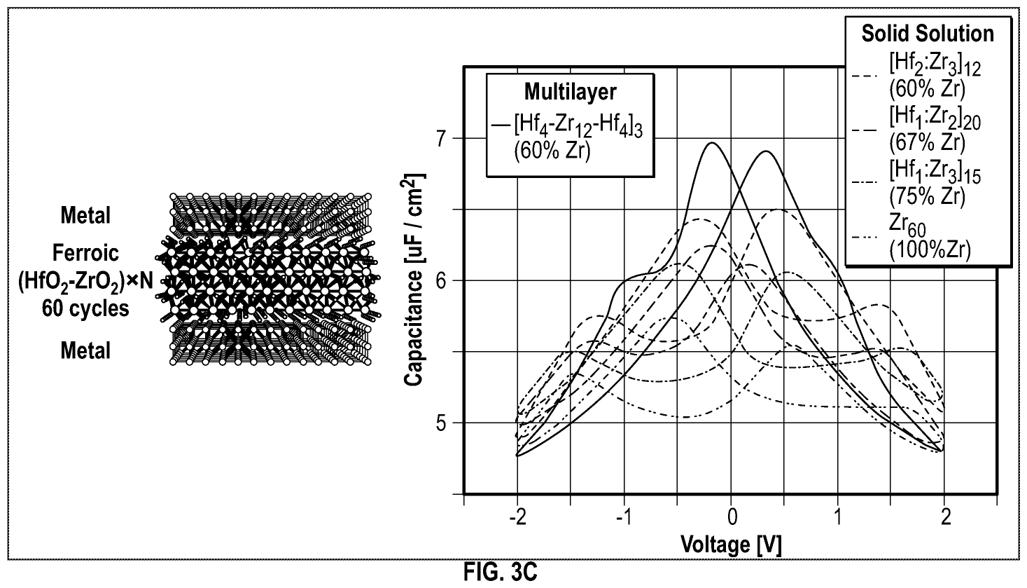

Next, the superlattices were grown on Si substrates in metal-oxide-semiconductor (MOS) capacitor structures. A self-limiting chemical oxide SiO₂ was grown first, resulting in ˜8.0-8.5 thickness, following the standard practice in advanced Si devices. Next, a 20-cycle thick multilayer was grown with ALD following the same stacking as before, that is, Hf:Zr: Hf 4:12:4. Accumulation C-V curves of the superlattice stack result in significantly larger capacitance in comparison with other conventional stacks—DE HfO₂, AFE ZrO₂, FE Zr:HfO₂—of the same 20 Å thickness (FIG. 2D). Furthermore, the Hf:Zr: Hf 4:12:4 trilayer demonstrates enhanced capacitance compared with a bilayer (Hf: Zr 8:12) and solid solution (Hf:Zr [2:3]₄) of the same thickness and Hf:Zr composition (FIG. 2E). Notably, the composition in the films as disclosed is close to the point at which several previous reports have discussed a possible morphotropic phase boundary (MPB) in thicker HfO₂—ZrO₂ solid solution films. Indeed, the origin of MPB lies in the flattening of the energy landscape. From this context, the negative curvature of the FE compensating the positive curvature of AFE is similar to obtaining MPB in these thin films. However, a critical distinction is the fact that, unlike the thicker films, MPB is not solely determined by volume fraction of the constituents. Rather, the overall flattening of the energy landscape is determined by stacking. For example, compared with solid solutions at the typically reported Zr-rich “MPB”-like compositions, the HfO₂—ZrO₂—HfO₂ trilayer demonstrates larger capacitance (FIGS. 3A, 3B, and 3C). This indicates the enhanced capacitance in HfO₂—ZrO₂ films is not simply driven by doping but instead can be tuned by the configuration of the multilayer structure (see also

FIGS. 7A to 7C). Overall, these capacitor studies suggest that the exact stacking sequence plays a crucial role in stabilizing the FE-AFE phase competition that leads to enhanced capacitance, akin to previous reports in perovskite-based FE-DE superlattices.

FIG. 2D shows metal oxide semiconductor (MOS) accumulation C-V of HfO₂—ZrO₂—HfO₂ trilayer compared with AFE ZrO₂, FE Zr:HfO₂, and high-κ dielectric HfO₂, all of the same thickness (20 Å) , indicating mixed-ferroic behavior is optimal for enhancing capacitance rather than purely FE or AFE behavior.

FIG. 2E shows accumulation C-V of the HfO₂—ZrO₂—HfO₂ trilayer compared with bilayer and solid-solution films of the same thickness (ALD cycles) and composition (Hf:Zr cycles), with an inset showing a diagram of multilayer (Hf and Zr cations vertically separated) versus solid solution (Hf and Zr cations intermixed). These results suggest that the capacitance enhancement in multilayer films is not simply driven by Hf:Zr composition but instead by the atomic-scale stacking (see also FIGS. 3A to 3C and 7A to 7C).

FIG. 3A to 3C illustrate solid solutions versus superlattice structure: the role of ALD period and Zr-content. FIG. 3A shows HfO₂—ZrO₂ multilayer and Zr-rich Hf:ZrO₂ solid solution films. With shorter ALD periods, the mixed FE-AFE multilayer structure transitions towards a Hf:ZrO₂ solid-solution with AFE-like behavior. In the solid solution state, the loss of the mixed ferroic order yields diminished capacitance due to the lack of mixed-ferroic-induced capacitance enhancement.

FIG. 3B shows MOS accumulation C-V of the HfO₂—ZrO₂—HfO₂ trilayer (60% Zr) compared with solid solution films of the same thickness (2 nm) and composition (60% Zr), as well as solid solution films of the same thickness and higher Zr-composition (67%-100% Zr).

FIG. 3C shows MIM C-V hysteresis loops of the HfO₂—ZrO₂ superlattice (60% Zr) compared with solid solution films of the same thickness (6 nm) and composition (60% Zr), as well as solid solution films of the same thickness and higher Zr-composition (67%-100% Zr). The Hf:ZrO₂ solid solution films with higher Zr content (60%-75%) are around the range attributed to the morphotropic phase boundary in thicker Hf:ZrO₂ alloys. These results indicate the capacitance enhancement in multilayer films is not simply driven by Zr-content but instead by the atomic-scale stacking, as the solid solution films with sub-atomic superlattice period do not demonstrate the same mixed ferroic behavior and enhanced capacitance as the superlattices.

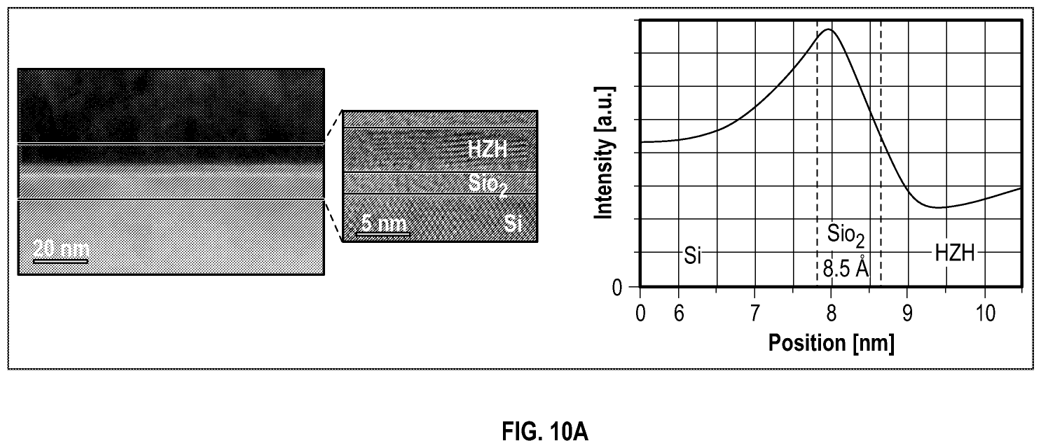

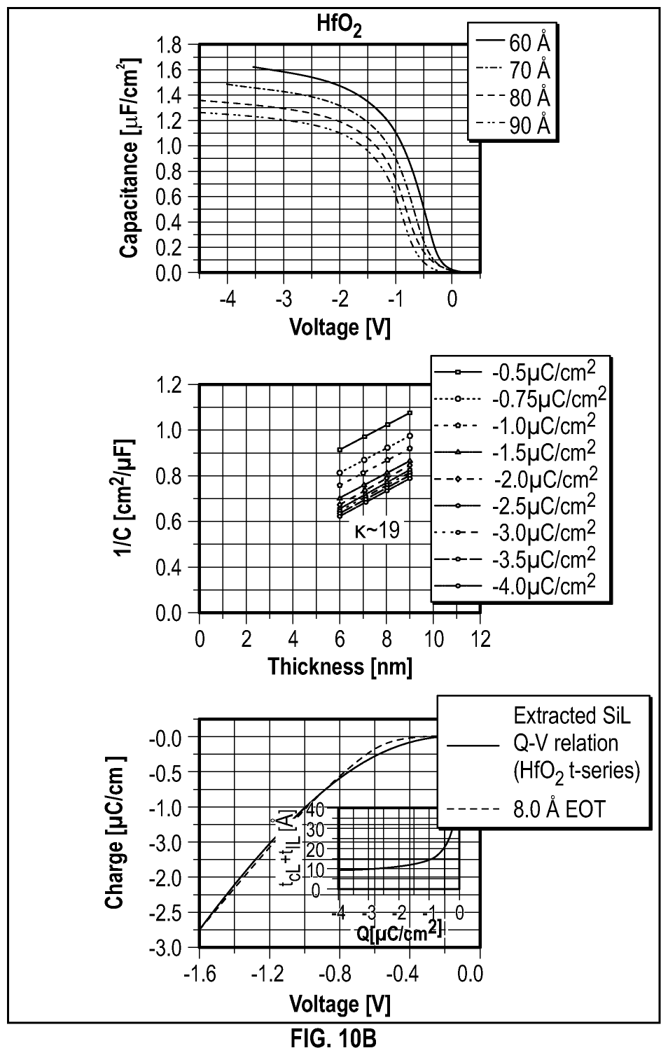

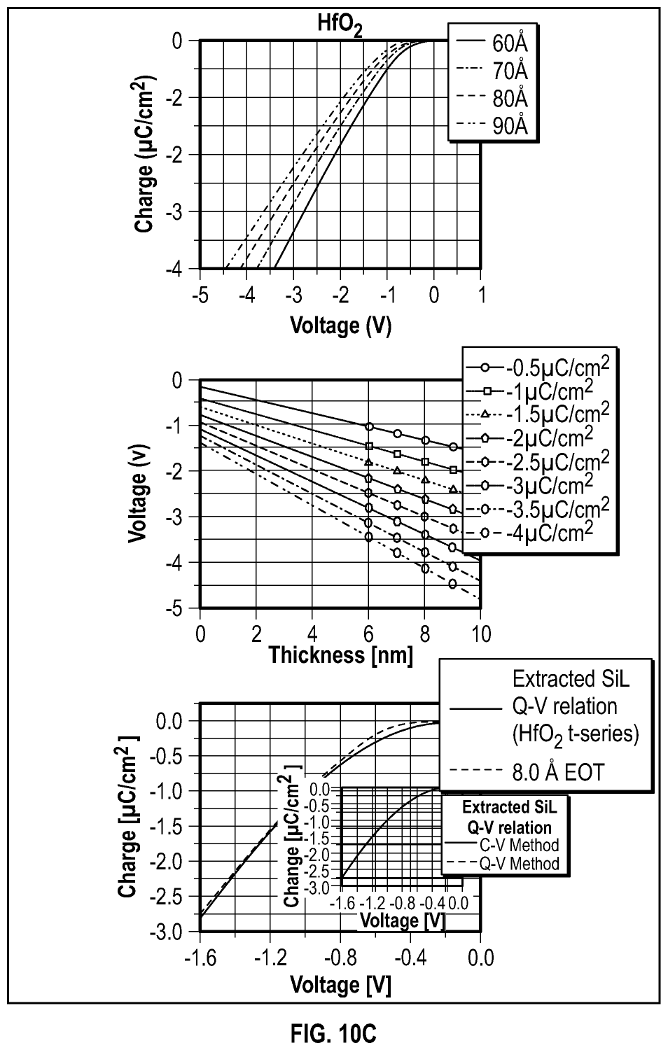

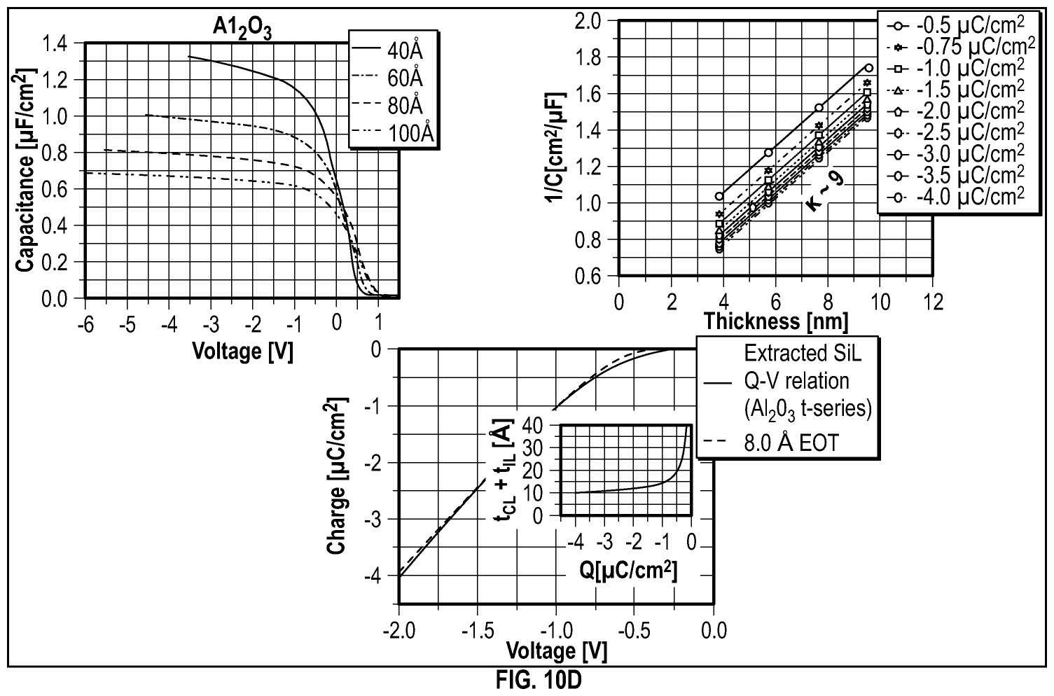

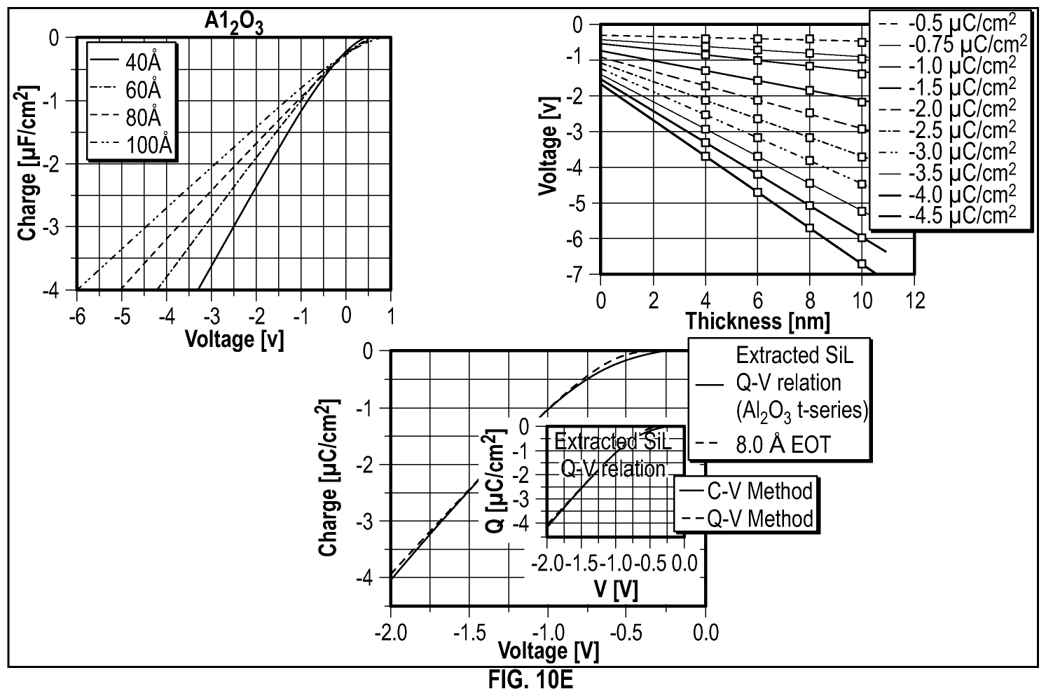

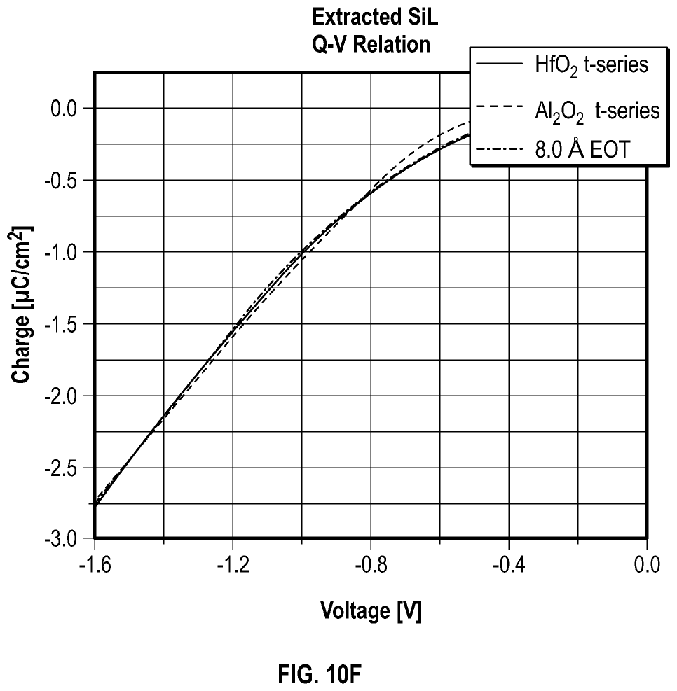

To quantify the observed capacitance, EOT simulations of MOS capacitors were performed using the industry standard model Synopsys simulation platform. The Hf:Zr:Hf 4:12:4 trilayer stacks vary between 6.5 Å and 7.0 Å EOT (FIG. 2F), consistent over many measured capacitors. Notably, this EOT is smaller than the expected thickness of the interfacial SiO₂ layer (8.0-8.5 Å), as mentioned previously. To investigate further, high-resolution TEM was performed on the disclosed gate stacks (see also FIGS. 10A to 10F), which illustrates the SiO₂ thickness is indeed ˜8.5 Å. To supplement this physical characterization, electrical characterization of the interfacial layer was implemented next via standard inverse capacitance vs. thickness analysis of conventional dielectric HfO₂ and aluminum oxide (Al₂O₃) thickness series grown on the same SiO₂ (see also FIGS. 10A to 10F). All thermal processing is kept exactly the same as the superlattice gate stack. The extracted HfO₂ and Al₂O₃ permittivity—19 and 9, respectively—is consistent with the typical dielectric phases of these two materials. Therefore, one can reliably extract the SiO₂ layer thickness, yielding 8 Å (see also FIGS. 10A to 10F), consistent with the high-resolution TEM results, similar to previously studies established by the semiconductor industry. Moreover, the consistent interlayer thickness extracted from both material systems indicates that neither Hf nor aluminum (Al) encroaches into the interfacial SiO₂, which would reduce its thickness and/or increase its permittivity. So considering the interfacial layer thickness as 8 Å, the Hf:Zr: Hf 4:12:4 gate stack demonstrates an overall EOT 1.0-1.5 Å lower than the constituent SiO₂ thickness. In other words, capacitance enhancement is observed in this 20 Å mixed ferroic gate oxide integrated on Si. Therefore, the mixed FE-AFE order not only improves the permittivity of the multilayer stack itself but also couples to the SiO₂ in MOS capacitor structures, yielding improved overall capacitance.

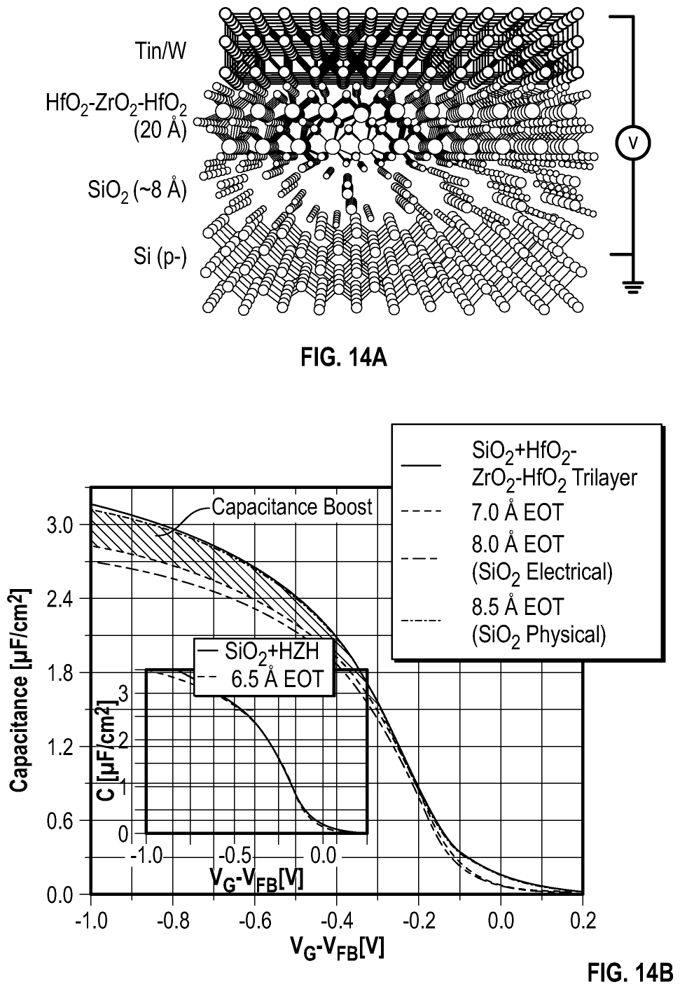

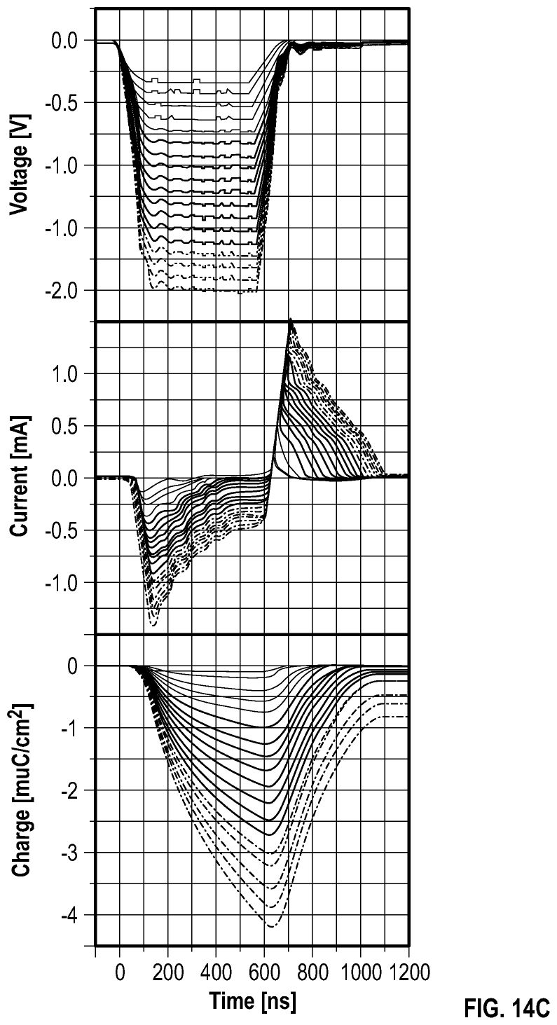

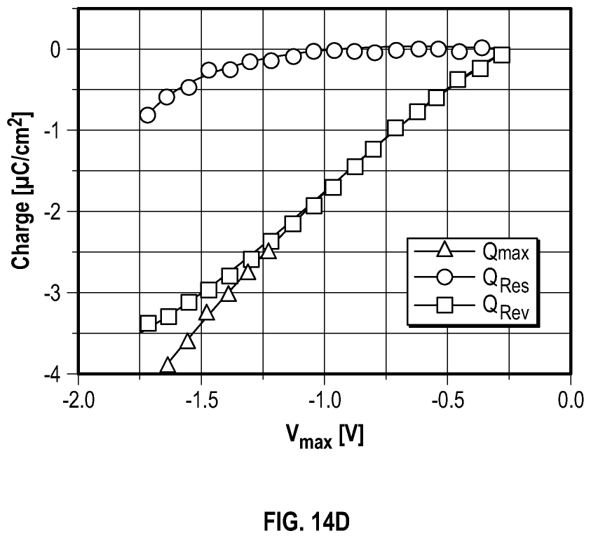

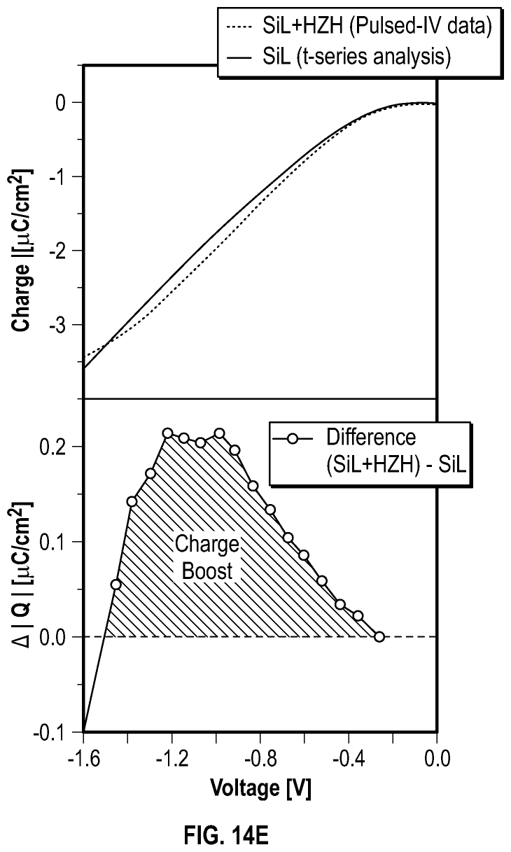

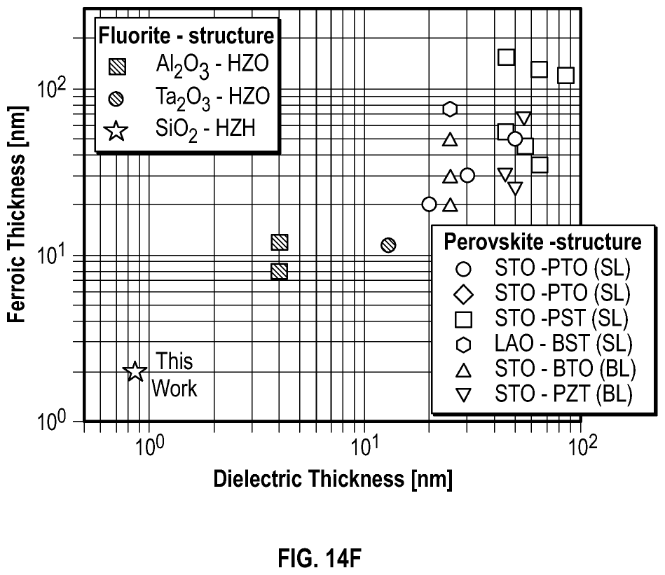

FIG. 2F shows accumulation C-V curves for a 2 nm HfO₂—ZrO₂—HfO₂ trilayer grown on sub-nanometer SiO₂ fit to effective oxide thickness (EOT) simulations; the inset shows externally verified MOS accumulation C-V of the same trilayer stack, demonstrating 6.5 Å EOT. The 2 nm trilayer on top of the SiO₂ demonstrates lower EOT than the thickness of the SiO₂ interlayer alone, carefully extracted via physical (8.5 Å) and electrical (8.0 Å) methodologies (see also FIGS. 10A to 10F), providing evidence of capacitance enhancement. Furthermore, these 2 nm ferroic gate stacks demonstrate amplified charge from pulsed current-voltage (I-V) measurements relative to the SiO₂ interlayer (see also FIGS. 14A to 14F). Notably, this 2 nm HfO₂—ZrO₂ multilayer on sub-nanometer SiO₂ provides the most scaled demonstration of charge and capacitance enhancement at the capacitor-level (see also FIGS. 14A to 14F).

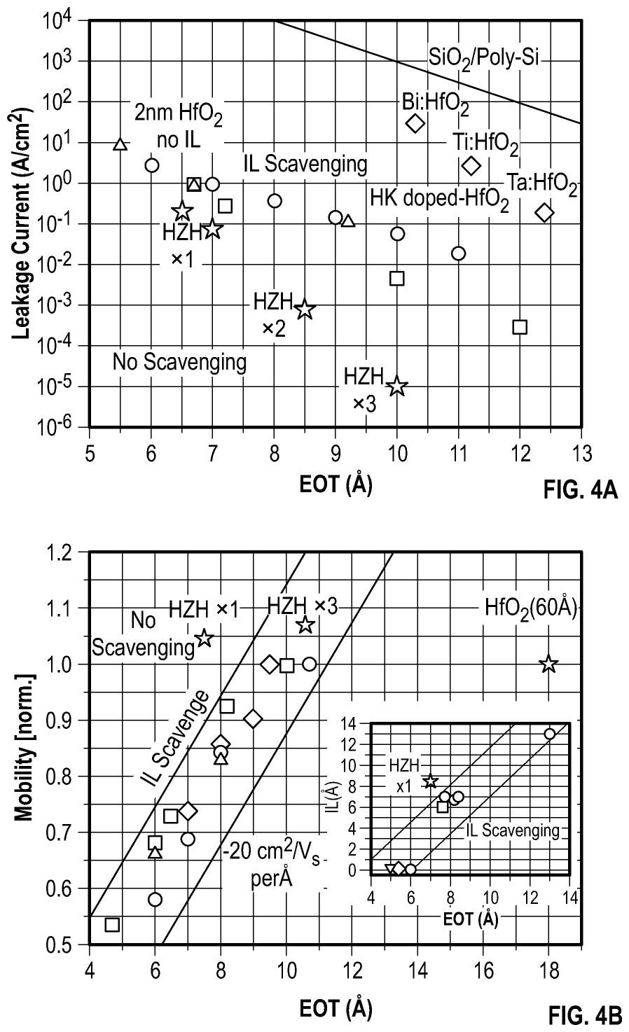

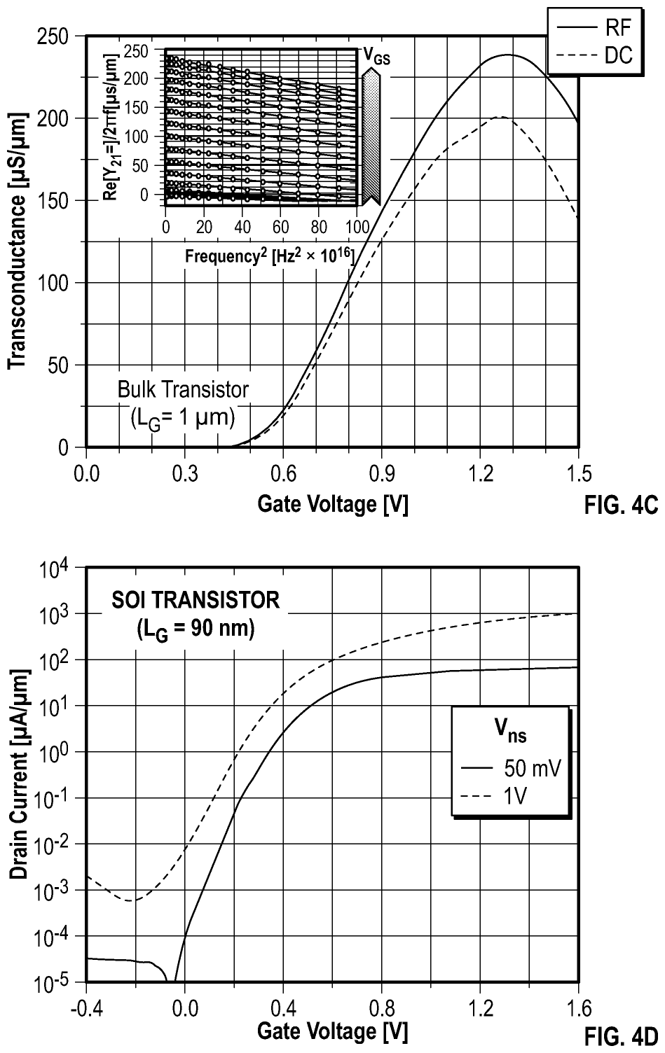

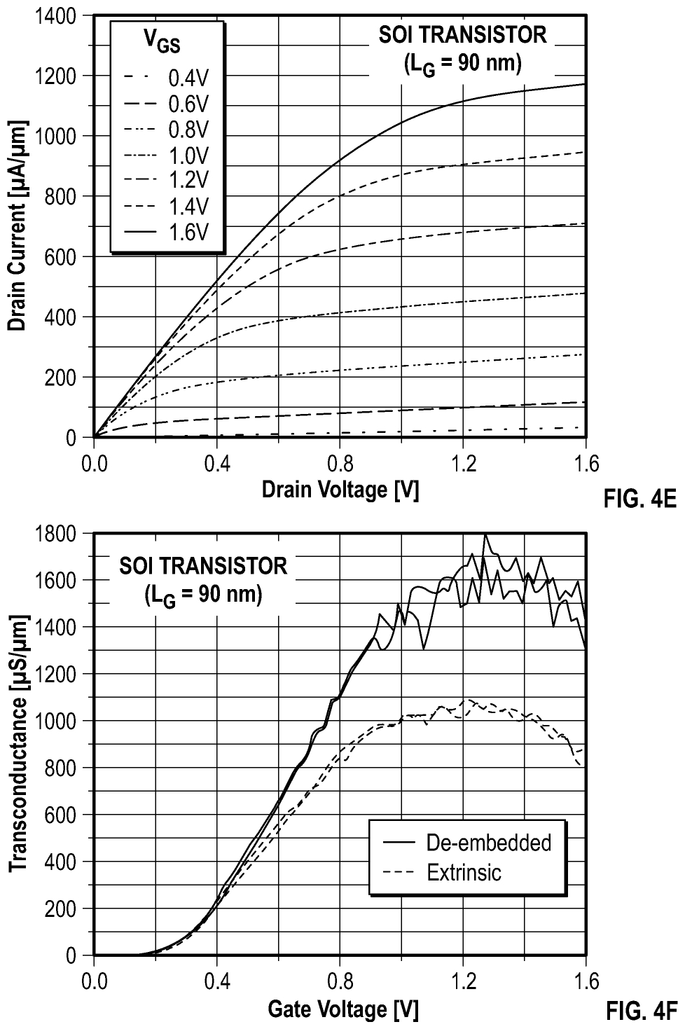

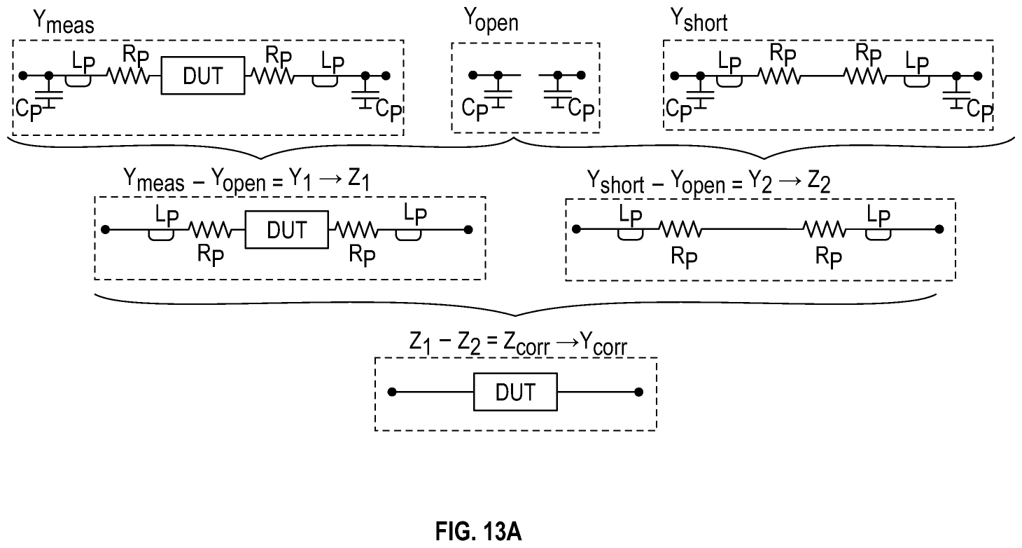

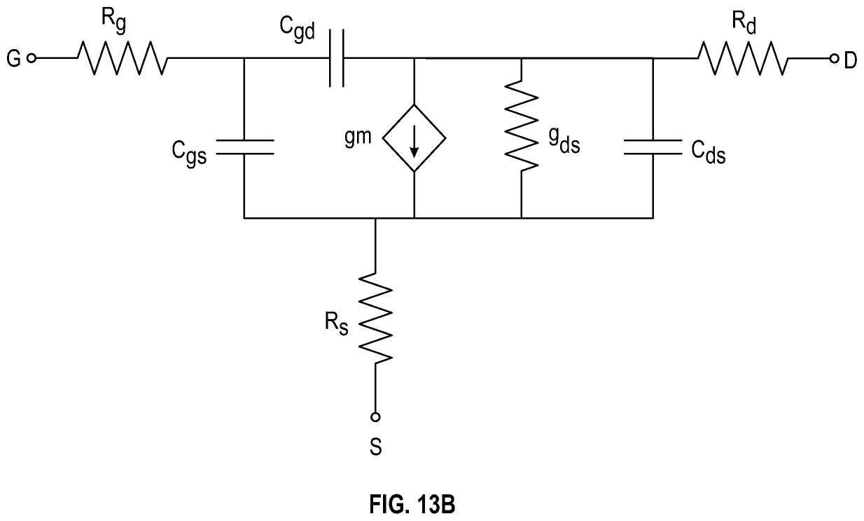

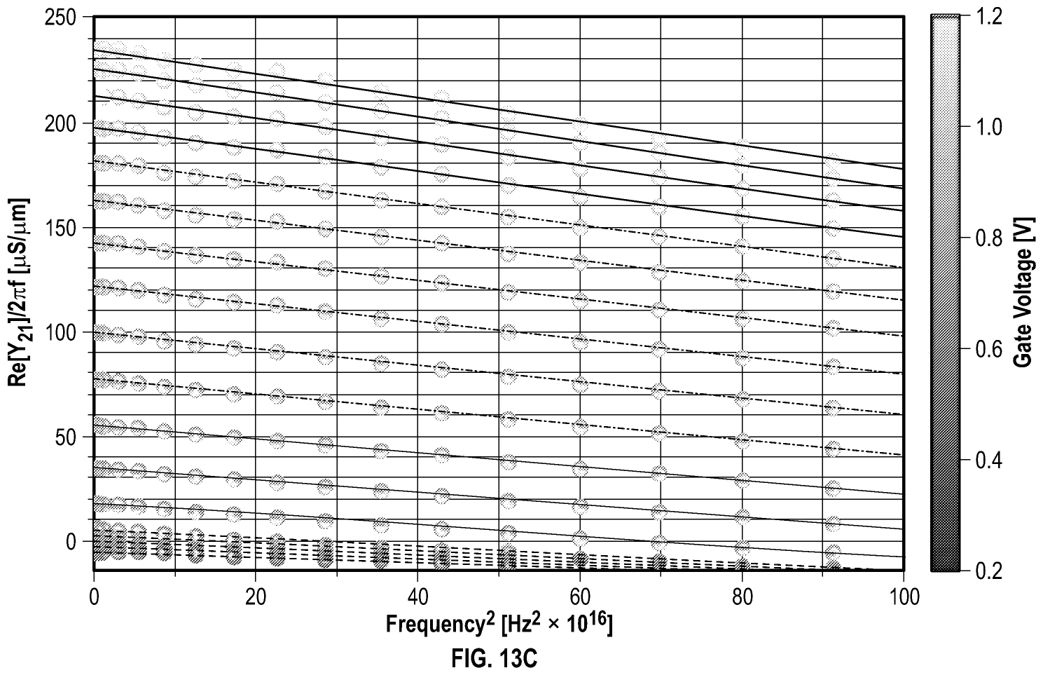

The practical implication of this capacitance enhancement can be clearly seen in FIG. 4A, which shows leakage current vs. EOT behavior. The leakage current is measured at V_{G}−V_{fb}=−1 V, where V_{fb} is the flatband voltage of the semiconductor. All other data points on this plot are taken from reported industrial gate stacks. The leakage current for the 4:12:4 stack is substantially lower at the same EOT. Note that below 9 Å, the other gate stacks need sophisticated scavenging techniques to reduce the thickness of the interfacial SiO₂. On the other hand, the structure of the present disclosure can reach ˜6.5 Å without any scavenging. This indicates that the leakage current for the stacks as disclosed is lower. Notably, the scavenging the interfacial SiO₂ leads to a loss of mobility due to increase in remote phonon scattering. As it has been shown, the mobility drops off with a slope of 20 cm²/V-s per every angstrom of scavenged SiO₂. To test how mobility is affected by the superlattice gate stack, long channel bulk transistors were fabricated with two different repeats of the superlattice, together with another sample that has thick (60 Å) HfO₂ as the gate stack. To extract mobility, a careful fitting of the measured C-V from the transistor structures is performed. In addition, series resistance is modeled from the data and de-embedded to reveal the intrinsic behavior. Next, the mobility is extracted using the peak transconductance method (see also FIGS. 13A to 13C). The mobility was found to remain essentially the same for all three stacks despite the difference in materials and EOT (from 2 nm EOT for HfO₂ down to <8 Å for the superlattice gate stack). First, this shows that there is no fundamental change in electron transport due to the use of the superlattice gate stack compared with standard HfO₂. In addition, it shows that there is no penalty in mobility even below an EOT of 9 Å, where conventional gate stacks show a degradation due to the need of scavenging. Because the absolute value of mobility depends on the specific processing technique, mobility numbers have been normalized in FIG. 4B. This clearly shows the flat behavior for the superlattice gate stack compared with the falling of trend for conventional gate stacks due to scavenging in the low EOT range.

FIGS. 4A to 4F illustrate device performance benefits utilizing ultrathin mixed-ferroic HfO₂—ZrO₂ gate stacks. FIG. 4A shows leakage-effective oxide thickness (J_{G}-EOT) scaling of the multilayer gate stacks (stars) benchmarked against reported high-κ metal gate (HKMG) literature, including interlayer-scavenged 2 nm HfO₂ (triangles, circles, squares), high-κ doped HfO₂ (diamonds), and SiO₂/poly-Si (negative sloped thin line). The leakage is the lowest reported for a 6.5-7.0 Å EOT MOS capacitor on silicon, due to the EOT reduction without requiring interlayer SiO₂ thickness reduction.

FIG. 4B shows normalized mobility versus EOT scaling of the multilayer gate stacks (stars) benchmarked against reported HKMG literature, including interlayer-scavenged 2 nm HfO₂ (triangles, circles, squares, diamonds) and hybrid silicate-scavenged interlayer (area between positive sloped thin lines), with an inset showing SiO₂ interlayer thickness versus EOT scaling comparing the 7.0 Å EOT HfO₂—ZrO₂—HfO₂ trilayer against notable HKMG literature, which employ interlayer scavenging to reduce EOT. For EOT scaling in conventional HKMG systems, the SiO₂ interlayer has to be reduced to lower EOT, which leads to degraded mobility. In this case, enhanced capacitance in HfO₂—ZrO₂ multilayers achieves scaled EOT without having to thin the SiO₂ interlayer; therefore, mobility is not degraded. The inset scatter plot highlights the underlying reason for the enhanced leakage-EOT and mobility-EOT behavior in the ultrathin trilayer gate stacks: low EOT without reduced SiO₂ interlayer thickness.

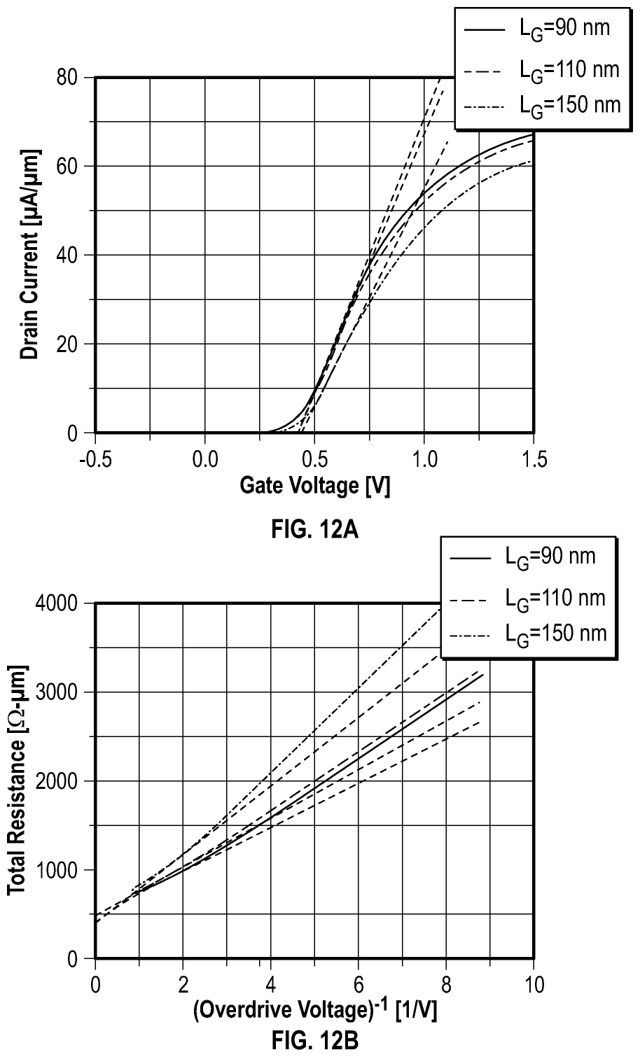

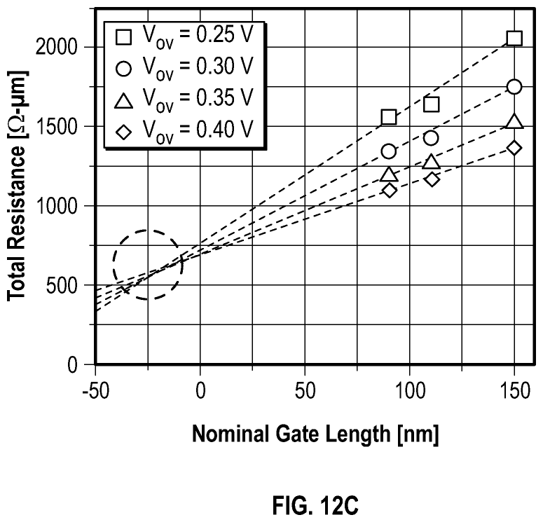

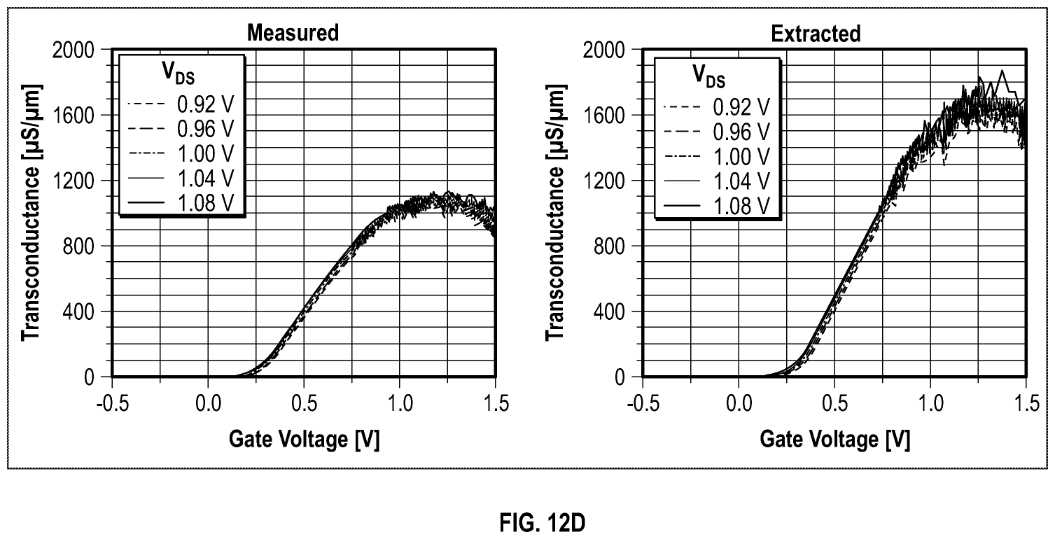

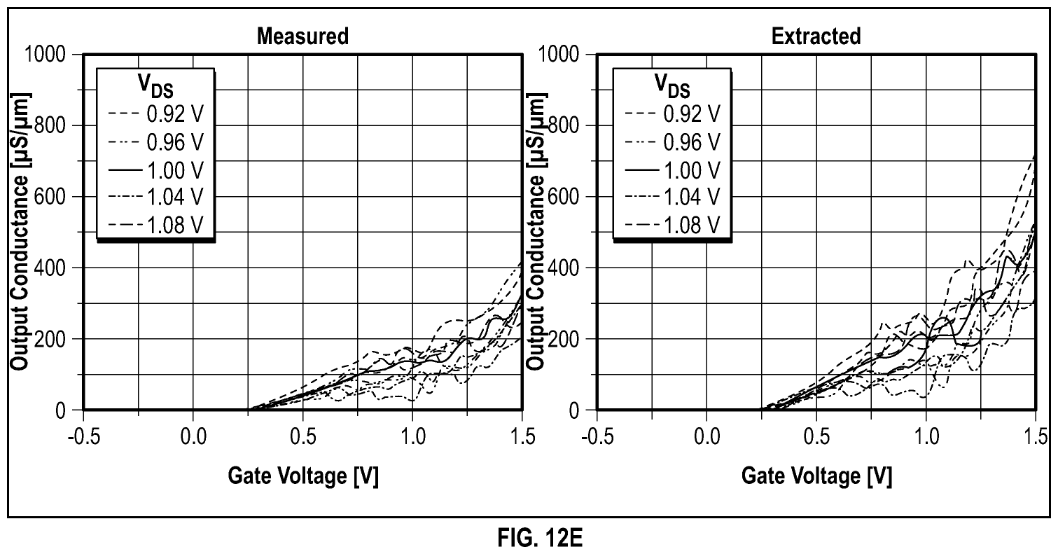

To examine how the capacitance enhancement behaves at high frequency, radio frequency measurements were performed on the same long channel (L_{G}=1 μm) devices (see also FIGS. 12A to 12F). This allows one to extract device parameters up to ˜800 MHz for the disclosed devices (close to the cut-off frequency). Of particular interest is the transconductance (gₘ), which is proportional to the product of capacitance and electron velocity (mobility). From Y-parameter measurements one can find alternating current (AC) transconductance as Re(Y₂₁)=gₘ+af², where f is the frequency (Methods). This yields an AC transconductance as a function of applied gate voltage (V_{G}). This dependence is plotted together with direct current (DC) transconductance (∂/_{D}/∂V_{G} from DC I_{D}-V_{G}; FIG. 4C). The DC and AC transconductances are similar with the AC transconductance being roughly 15% larger at the peak value. The hypothesis is that this slightly large AC transconductance results from the fact that certain interface traps, which affect the DC behavior, cannot respond at frequencies larger than 100 MHZ, leading to better gate control. More importantly, these results show that the capacitance enhancement is not limited to low frequencies.

FIG. 4C is a graph showing gm versus gate voltage (V_{G}) for long-channel bulk transistors (L_{G}=1 μm) obtained from both direct current (DC) (derivative of I_{D}-V_{G}) and radio frequency (Re[Y₂₁]) measurements at V_{DS}=1 V; V; the inset shows de-embedded Re[Y₂₁] (open circles) as a function of squared frequency at different DC V_{GS} bias points extrapolated to the zero frequency limit (dotted lines) to extract the RF gm (see also FIGS. 13A to 13C). The high-frequency measurements help suppress defect contributions that would otherwise dampen the intrinsic gₘ.

Finally, to test the ON current capability, a L_{G}=90 nm device was fabricated on a SOI transistor with 18 nm SOI thickness and the superlattice gate stack. The transfer and output characteristic of a typical transistor are shown in FIGS. 4D and 4E. Note that the threshold voltage of this device is 0.55 V, which is consistent with the work function of tungsten used as the gate metal. Because of this, the transistors have been driven up to 1.6 V gate voltage so that an overdrive voltage (Vₒᵥ=V_{G}−V_{T}) of ˜1 V can be applied. It is found that at a drain voltage (V_{D}) and Vₒᵥ of 1 V, the drain current exceeds 1 mA/μm. In addition, as shown in FIG. 4F, the measured extrinsic transconductance is ˜1.1 μS/μm, which gives an intrinsic transconductance of ˜1.75 μS/μm (see also FIGS. 14A to 14F). These values of ON current and transconductance are substantially larger than a conventional 90 nm transistor and result from the large capacitance provided by the superlattice gate stack and the fact that the low EOT resulting from the stack does not affect the electron transport adversely.

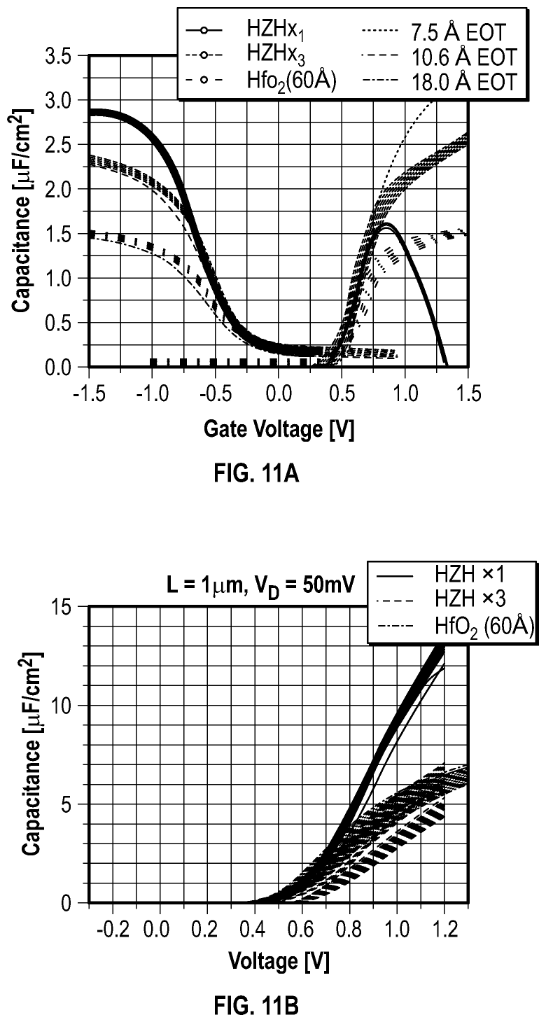

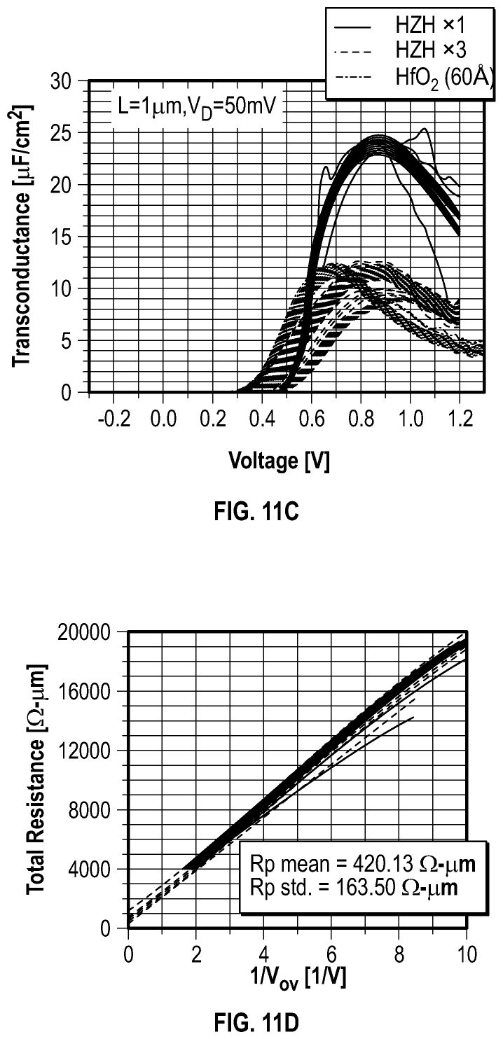

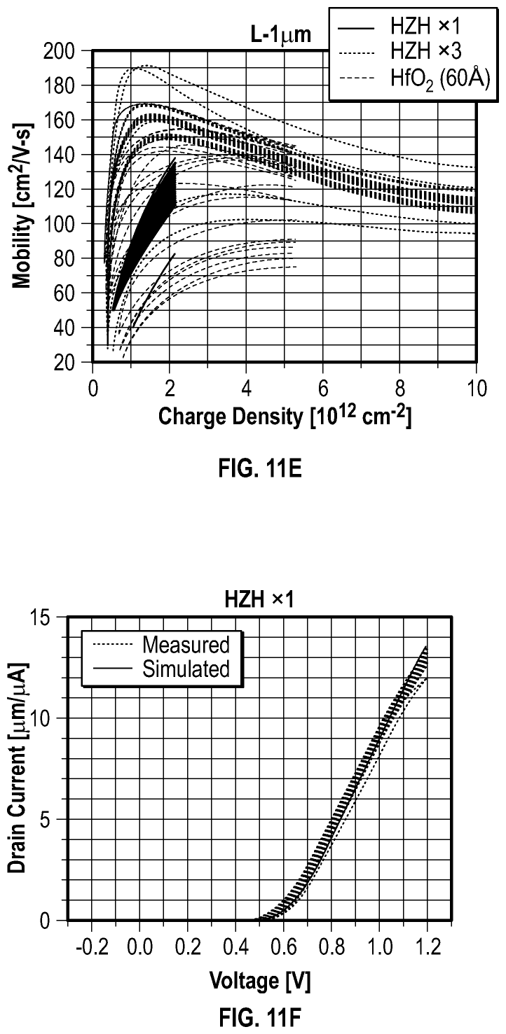

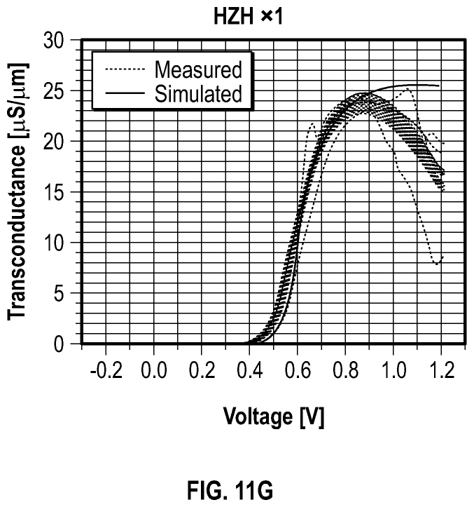

FIGS. 4D, 4E, and 4F show DC I-V transfer characteristics (I_{D}-V_{G}), DC output characteristics (I_{D}-V_{D}), and DC transconductance (gₘ-V_{G}), respectively, for short-channel (L_{G}=90 nm) silicon-on-insulator (SOI) transistors. Notably, the maximum on-current and gₘ at V_{DS}=1 V exceeds 1 μA/μm and 1 mS/μm. Direct current mobility and transconductance values are carefully extracted after de-embedding the series resistance from double-swept I-V measurements (see also FIGS. 11A to 11F and FIGS. 12A to 12F, respectively).

With the superlattice gate stack demonstrated in integrated Si devices, we return to the capacitance enhancement observed in this gate stack. As previously discussed, the mixed FE-AFE order facilitates a flatter energy landscape where the negative curvature of the FE phase is compensated by the positive curvature of the AFE phase. Notably, when the mixed ferroic oxide is grown on an SiO₂ interlayer, it can lead to similar compensation again. As observed in the thicker FE-AFE superlattice MIM capacitors, some hysteresis still remains, which manifests at large voltages, indicative of a negative curvature regime still persisting in the superlattices. The interfacial DE SiO₂ can flatten out that energy landscape even further, thus leading to enhanced capacitance. This is similar to the negative capacitance and resultant capacitance enhancement observed in FE-DE series combinations. To supplement the C-V evidence of capacitance enhancement (FIG. 2F), pulsed electrical measurements of the superlattice gate stack MOS capacitors, which can quantify the amount of stored charge as a function of voltage, demonstrate larger stored charge than if just interfacial SiO₂ was sitting on top of Si, providing further evidence of negative capacitance in the gate stack (see also FIGS. 14A to 14F). Note that previous studies have shown that negative capacitance stabilization is favored under states of high susceptibility. As disclosed, the competing ferroic order in HfO₂—ZrO₂ multilayers substantially increases its susceptibility and is thus expected to facilitate negative capacitance behavior when placed on top of the interfacial SiO₂.

Capacitance enhancement has been demonstrated in single-crystalline, perovskite-structure ferroelectric-dielectric superlattices by many groups. The present disclosure demonstrates that the same enhancement is possible in HfO₂—ZrO₂ fluorite-structure superlattices exhibiting mixed ferroelectric-antiferroelectric order in films as thin as just ˜2 nm. The ability to control ferroic order in such ultrathin films is of critical importance for advanced electronic devices, considering previous studies have shown that negative capacitance can be stabilized under states of high susceptibility.

Furthermore, the present disclosure establishes the critical role of atomic-layer stacking, as opposed to conventional doping techniques, in controlling the ferroic phase space and permittivity of fluorite-structure oxides down to ultrathin limits, leveraging its unique size effects and rich antiferroelectric-ferroelectric polymorphs. When this mixed phase HfO₂—ZrO₂ multilayer is integrated on Si, the gate stack exhibits a capacitance enhancement, lowering the EOT below the thickness of SiO₂ itself, which would not be possible with a conventional dielectric. Notably, the lowest EOT achieved (6.5 Å) for the gate stack and interfacial SiO₂ together is lower than that used in the most advanced Si transistors today. Therefore, the present disclosure demonstrates that harnessing atomic-scale layering in ultrathin HfO₂—ZrO₂ ferroic gate oxides presents a promising materials design platform for future Si transistors beyond conventional high-κ dielectrics that has enabled the semiconductor industry over the past two decades.

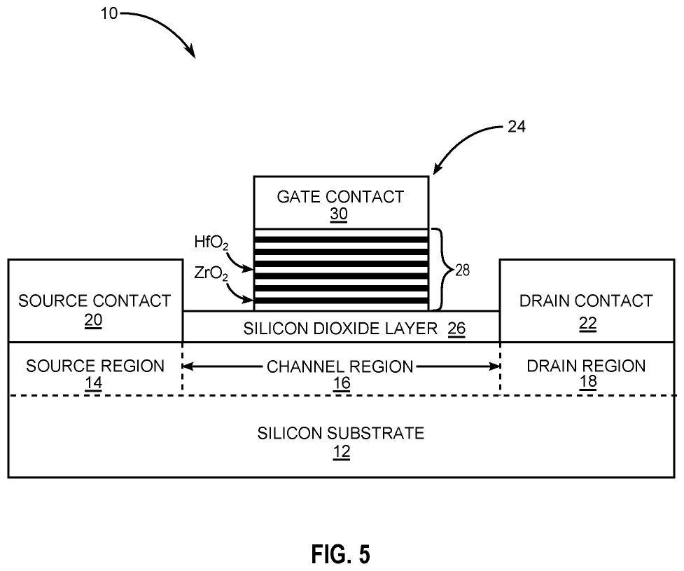

FIG. 5 is a cross-sectional view of an exemplary embodiment of a semiconductor device 10 in the form of an advanced transistor that is in accordance with the present disclosure. In this exemplary embodiment, the semiconductor device 10 has a semiconductor substrate 12 having a source region 14, a channel region 16 spaced from the source region 14, and a drain region 18 spaced from both the source region 14 and the channel region 16 with a source contact 20 disposed over the source region 14, a drain contact 22 disposed over the drain region 18, and a gate stack 24. The gate stack 24 includes an oxide layer 26 disposed over the channel region 16, a periodic sequence of (HfO₂—ZrO₂)×N material layers 28 disposed over the oxide layer 26, wherein N is a natural counting number, and a gate contact 30 disposed over the periodic sequence of (HfO₂—ZrO₂)×N material layers 28.

### METHODS

### Gate Stack

### Gate Oxide.

Thin films of HfO₂—ZrO₂ were grown by ALD in a Fiji Ultratech/Cambridge Nanotech tool (University of California, Berkeley) at 270° C., in which tetrakis (ethylmethylamino) hafnium and tetrakis (ethylmethylamino) zirconium precursors are heated to 75° C. and water vapor is used as the oxidant. For metal-ferroelectric-insulator-semiconductor capacitor structures, sub-nanometer chemically grown SiO₂ on lightly doped Si (10¹⁵ cm⁻³) was prepared by the standard clean (SC-1) solution (5:1:1 H₂O:H₂O₂:NH₄OH at 80° C. for 10 minutes) after the Si wafer was cleaned in Piranha (120° C. for 10 minutes) to remove organics and hydrogen flouride (HF) (50:1 H₂O:HF at room temperature for 30 s) to remove any native oxide. Subsequently, HfO₂—ZrO₂ multilayers are deposited at 270° C. by ALD. After ALD deposition, post-deposition annealing was performed at 175° C. (20 min, forming gas N2/H₂ background) to help cure the SiO₂-oxide interface. For confirmation and reproducibility, HfO₂—ZrO₂ multilayers of the same ALD cycling were also deposited at MIT Lincoln Laboratory; after ALD deposition, post-deposition annealing was performed at 250° C. (1 min, N₂ background).

### Gate Metal.

For capacitors as embodied in the present disclosure, the first layer of the gate metal, titanium nitride (TiN), is deposited by ALD (250° C., 20 cycles, 15 Å) in N₂ and H₂ plasma. Subsequently, tungsten (W) is deposited by sputtering (room temperature, 60 nm). For MIT Lincoln Laboratory capacitors, the gate metal, TiN, is deposited by physical vapor deposition (room temperature).

### Annealing.

The entire gate stack undergoes a low-temperature post-metal anneal (200° C., 1 min, N₂) to cure interface defects. This low temperature does not interfere with the HfO₂—ZrO₂ multilayer structure, as confirmed by various characterization techniques (FIGS. 6A to 6D) and maintains the mixed ferroic behavior, as high-temperature annealing would induce purely ferroelectric behavior (FIGS. 7A to 7C). X-ray diffraction and TEM confirm the presence of crystalline ultrathin films despite the low deposition temperature, afforded by the low crystallization temperature of ZrO₂. In fact, non-post-annealed ALD-grown ZrO₂ has previously demonstrated crystallization into the ferroelectric orthorhombic phase on Si.

FIGS. 6A to 6D illustrate an atomic-scale multilayer structure. FIG. 6A shows the HfO₂—ZrO₂ multilayer structure on SiO₂-buffered silicon.

FIG. 6B shows synchrotron XRR of thicker HfO₂—ZrO₂ heterostructures (left) repeated with the same periodicity as the thinner trilayer structure; and the XRR fitting (right) demonstrates the presence of well-separated HfO₂—ZrO₂ layers, that is, not a solid-solution, for three different multilayer repeats of fixed periodicity.

FIG. 6C shows layer-resolved EELS of the 2 nm HfO₂—ZrO₂—HfO₂ trilayer, which again shows clear separation of HfO₂—ZrO₂ layers following the expected 4 Å-12 Å-4 Å HfO₂—ZrO₂—HfO₂ structure.

FIG. 6D illustrates angle-resolved XPS of the 2 nm HfO₂—ZrO₂—HfO₂ trilayer (left) and the extracted atomic composition (right); the presence of increasing Zr-content as the grazing angle increases is expected from the multilayer structure.

FIGS. 7A to 7C illustrates solid solutions versus superlattice structure: role of annealing temperature. FIG. 7A shows HfO₂—ZrO₂ multilayer and Hf:ZrO₂ solid solution films. Under a high-temperature anneal, the multilayer structure transitions towards a Hf:ZrO₂ solid-solution-like structure demonstrating more FE-like behavior. In the solid solution state, the loss of the mixed ferroic order yields diminished capacitance due to the lack of both the higher-permittivity AFE phase and the mixed-ferroic-induced capacitance enhancement.

FIG. 7B shows a comparison of MOS capacitor accumulation C-V characteristics in HfO₂—ZrO₂ multilayers, where the heterostructure was repeated (top center) 1 time, (bottom left) 2 times, or (bottom right) 3 times, under both low-temperature and high-temperature anneals.

FIG. 7C is a diagram showing a comparison of mixed-ferroic behavior in low-temperature treated MIM HfO₂—ZrO₂ multilayers versus FE behavior in in the same multilayers annealed at high temperatures, where the heterostructure was repeated (top center) 3 times, (bottom left) 4 times, or (bottom right) 5 times. In all instances, the high-temperature anneal (>500° C.) results in diminished accumulation capacitance compared with the low-temperature anneals, as the multilayered mixed-ferroic films presumably transition to more FE-like solid-solution alloys.

### Device Fabrication

### MOS and MIM Capacitors.

For MOS capacitor structures, after gate stack deposition, top electrodes are defined by photolithography and dry etching. For bare structures (structural studies), the top metal is removed by chemical etching to expose the gate oxide surface. For MIM capacitors, W is deposited by sputtering (room temperature, 30 nm) on a lightly doped Si substrate as the bottom metal electrode. After ferroic film deposition by ALD, 60 nm of W is deposited by sputtering. The top electrodes are then defined by photolithography and dry etching.

### Bulk Transistors.

The n-type bulk transistors were fabricated by a non-self-aligned gate-last process on bulk silicon wafers (10¹⁷cm⁻³) with local oxidation of silicon as device isolation technique. First, a 10 nm of SiO₂ thermal oxide and a 30 nm of low-pressure chemical vapor deposition silicon nitride (Si₃N₄) were grown on the Si substrates. After the active region was defined by photolithography and Si₃N₄/SiO₂ etching, the dry oxidation was performed to form the local oxidation of silicon isolation. Next, the source/drain regions were defined by photolithography and ion implantation with an ion dose of 3×10¹⁵ ions/cm². The dopants were then activated by rapid thermal anneal at 900° C. for 7 min in N₂ ambient. The gate stacks with the sub-nanometer chemically grown SiO₂, 2 nm HfO₂—ZrO₂ heterostructure, and 100 nm of sputtered W gate were then deposited. After the gate fingers (from 500 nm to 50 μm) were patterned by photolithography and etched by inductively coupled plasma metal etching, the 400 nm thick interlayer dielectric SiO₂ was then deposited using plasma-enhanced chemical vapor deposition. Last, after the contact hole opening, the Ti/TIN contact metal was deposited by sputtering, defined by photolithography, and then etched by inductively coupled plasma metal etching.

### Short-Channel SOI Transistors.

The n-type short-channel transistors were fabricated by a non-self-aligned gate-last process on SOI substrates with a gate length (L_{G}) down to 90 nm. First, the device layer was thinned down to 20 nm and the active regions were defined by photolithography with expose regions etched slightly into the buried oxide. The hydrogen silsequioxane negative resist were written by e-beam lithography as a hard mask for the ion implantation with a dose of 5×10¹⁵ ions/cm². The dopant activation was conducted in an rapid thermal anneal at 900° C. for 15 seconds in N₂ ambient. The gate stacks with the sub-nanometer chemically grown SiO₂, 2 nm HfO₂—ZrO₂ heterostructure, 1.5 nm of plasma-enhanced ALD TiN, and 100 nm of sputtered W were sequentially deposited. The gate region (250 nm) was then patterned by photolithography. Like the backend process for the bulk transistors, a 400 nm of interlayer dielectric and a sputtered Ti/TiN contact metal were deposited and defined by photolithography and inductively coupled plasma etching.

### Microscopy

### Transmission Electron Microscopy.

Electron microscopy was performed at the National Center for Electron Microscopy facility of the Molecular Foundry at Lawrence Berkeley National Laboratory. The high-resolution resolution bright field TEM images of HfO₂—ZrO₂ thin films were performed by FEI ThemIS 60-300 microscope with image aberration corrector operated at 300 kV (FIG. 1D; FIGS. 8E and 8F). To prepare cross-sectional TEM samples of HfO₂—ZrO₂ thin films, mechanical polishing was employed by using an Allied High Tech Multiprep at a 0.5° wedge to thin down the total thickness of samples down to 10 μm. Later, argon (Ar) ion milling of the Gatan Precision Ion Milling System was utilized to make an electron-transparent sample, starting from 4 keV down to 200 eV as final cleaning energy. The local interplanar d-spacing in HfO₂—ZrO₂ thin films was measured by DigitalMicrograph software using line profile with integration width. The SiO₂ interlayer thickness in wide field-of-view was measured by the same method.

FIGS. 8A to 8F illustrates ferroic phase insights from structural characterization. FIGS. 8E and 8F are TEM micrographs showing additional cross-sectional evidence of T-phase and O-phase, respectively, in which the extracted T-(101) lattice spacing (˜2.95 Å) and O-(111) lattice spacing (˜3.08 Å) is consistent with that extracted from IP-GiD.

### Optical Microscopy.

Second harmonic generation (SHG) measurements (FIG. 8D) were performed with a Ti:sapphire femtosecond laser (Tsunami, Spectra Physics, λ˜800 nm, frequency ˜80 MHZ). The linearly polarized femtosecond laser beam was focused through 50× objective lens (NA˜0.42) which results in a focal spot size of 2 μm. The generated SHG signal was collected through the same objective lens and separated from the fundamental beam by the harmonic separator. After passing through the optical bandpass filter, the SHG signals were registered to the photon multiplier tube without a polarizer. The fundamental beam was mechanically chopped, and the signal collected by the photon multiplier tube was filtered by a lock-in amplifier to reduce the background noise. For SHG spatial mapping, a two-axis piezo stage was utilized and the coordinate was synchronized with the photon multiplier tube signal. The SHG intensity was obtained by averaging the mapping signals across a 100 μm×100 μm sample area.

FIG. 8D shows SHG mapped across a bare 2 nm HfO₂—ZrO₂—HfO₂ trilayer; the presence of SHG intensity demonstrates the inversion symmetry breaking present in these ultrathin ferroic films.

### X-Ray Characterization

### X-ray Reflectivity.

Synchrotron X-ray reflectivity—performed at Sector 33-BM-C beamline of the Advanced Photon Source, Argonne National Laboratory and at Beamline 2-1 of the Stanford Synchrotron Radiation Lightsource, SLAC National Accelerator Laboratory-confirmed the thickness of HfO₂—ZrO₂ heterostructures (FIG. 6B). The overall thickness of the HfO₂—ZrO₂ heterostructures is consistent with the growth rate (˜1 Å/cycle) of ALD-grown Zr: HfO₂. Furthermore, the presence of irregularly spaced fringes in the thicker HfO₂—ZrO₂ heterostructures suggests the presence of well-separated HfO₂—ZrO₂ layers, that is, not a solid solution. This is confirmed by XRR fitting (FIG. 6B) performed with the python package GenX50, which considers factors such as density, roughness, and thickness.

### Grazing Incidence Diffraction: In-Plane.

Synchrotron in-plane grazing-incidence diffraction (GID) (FIG. 1E and FIG. 8A) was performed at Sector 33-ID-D beamline of the Advanced Photon Source, Argonne National Laboratory. A Pilatus 100 K Area Detector collected diffraction flux from the in-plane grazing incidence geometry; the region of interest on the Pilatus detector was set long in the vertical direction to amplify the relevant diffracted flux. In-plane GID fixed the out-of-plane grazing angle (δ=0.9°) while the detector was swept in-plane (v spanned 8°-50°); the corrected Bragg angle (2θ) over which the data is plotted and indexed is determined from the relationship cos 20 =cosv . cos o set by the geometry of the experimental setup. The X-ray source was fixed at 16 keV (λ=0.775 Å) . In-plane geometry allows for sampling of multiple lattice planes and finer-width reflections to enable clear indexing to the ferroelectric orthorhombic (Pca2₁) and antiferroelectric tetragonal (P4₂/nmc) fluorite structure in HfO₂—ZrO₂ heterostructures. The presence of many reflections from the in-plane GID spectra allow for clear distinction from other nonpolar fluorite-structure polymorphs (FIG. 1E; FIG. 8A). Such diffraction spectra would be otherwise prohibited in typical out-of-plane geometry due to the lack of vertical diffraction planes and the large linewidth inherent to nanometer-thick films; only a few large-linewidth reflections are present in previous out-of-plane GID scans of 1 nm Zr:HfO₂.

FIG. 8A illustrates in-plane synchrotron GID of a bare HfO2—ZrO₂—HfO₂ trilayer indexed to the tetragonal/orthorhombic phases (left); a zoom-in of in-plane GID around orthorhombic (111) peak and tetragonal (101) peaks, confirming the presence of mixed ferroic order in the HfO₂—ZrO₂—HfO₂ trilayer (center); and differentiation of the two peaks by performing detailed indexing of the entire spectrum, which largely indexed to the orthorhombic phase (right). Lattice parameters corresponding to the orthorhombic phase, determined from the {200} family of reflections, are self-consistently checked against the (111) lattice spacing as well as other higher-order reflections present at higher angles. As seen in the table in FIG. 8A, the extracted lattice parameters correspond well to extracted Bragg d-spacing.

### Two-Dimensional Diffraction.

Two-dimensional reciprocal space maps (FIGS. 8B and 8C) were measured at Beamline 11-3 of the Stanford Synchrotron Radiation Lightsource, SLAC National Accelerator Laboratory. Rayonix MX225 CCD area detector collected diffraction flux in gazing incidence (<0.20° geometry; the X-ray source (50 microns vertical×150 microns horizontal beam size) was fixed at 12.7 keV. The sample-detector work distance was set to 80 mm to enable detection of a wide region of reciprocal space (Q-range 0.2 Å⁻¹ to 5 Å⁻¹) at the expense of real space resolution (d-spacing or θ). The two-dimensional diffraction scans, in which a wide portion of the entire reciprocal space was collected simultaneously rather than at discrete regions in Qx-Qy space, were averaged over data collection time and for repeated scans. These measurement features, in tandem with the high X-ray flux afforded by the synchrotron source, enabled sufficient diffraction signal detection and contrast in films just one nanometer in thickness. Data analysis was performed by Nika, an Igor Pro package for correction, calibration, and reduction of two-dimensional areal maps into one-dimensional data. Two-dimensional reciprocal space maps on bare HfO₂—ZrO₂ heterostructures confirm the presence of crystalline ultrathin films despite the low deposition temperature, afforded by the low crystallization temperature of ZrO₂ on Si.

FIG. 8B illustrates the two-dimensional reciprocal space map of a bare 2 nm HfO₂—ZrO₂—HfO₂ trilayer indexed to the tetragonal/orthorhombic phases by indexing integrated diffraction spectrum. The lack of fully polycrystalline rings demonstrates that these 2 nm HfO₂—ZrO₂—HfO₂ trilayers are highly-oriented, consistent with TEM imaging.

FIG. 8C illustrates synchrotron X-ray absorption spectroscopy (XAS) of a bare 2 nm HfO₂—ZrO₂—HfO₂ trilayer at the Hf M₃ (left) and Zr L_{3,2} edges (center): the presence of linear dichroism (orbital polarization) provides further evidence of symmetry-breaking in these oriented thin films.

Ferroic Phase Identification from Diffraction.

For fluorite-structure thin films, the main phases to consider are the dielectric monoclinic (P2₁/c), antiferroelectric tetragonal (P4₂/nmc), and ferroelectric orthorhombic phases (Pca21). Various diffraction reflections from the wide-angle in-plane grazing incidence diffraction spectra enable indexing to the orthorhombic Pca2₁ phase. Lattice parameters (a, b, c), determined via Bragg's law from the d200 family of reflections, are self-consistently checked against the (111) lattice spacing

$$\frac{1}{{d}_{111}^{2}} = \frac{1}{{a}^{2}} + \frac{1}{{b}^{2}} + \frac{1}{{c}^{2}} ,$$

as swell as other higher-order reflections present in the in-plane diffraction spectra (FIG. 8A). For example, the lattice parameters extracted from the {200} peaks were a=5.36 Å, b=5.23 Å, and c=5.47 Å. This corresponds to a d211 lattice spacing of 2.209 Å, which agrees well with the lattice spacing (2.205 Å) obtained from Bragg's law based on the peak position (FIG. 8A).

The monoclinic phase was ruled out due to a lack of two {111} peaks in the diffraction spectra and the (111) peak being significantly offset from its expected peak position in the monoclinic phase. With regard to the indexing of tetragonal (101) peak, it is always reported that the tetragonal (101) reflection has a smaller d-spacing in thicker HfO₂-based films and is therefore expected to be present at a higher angle compared with the orthorhombic (111) reflection, which is the case in the indexed diffraction spectra (FIG. 8A). In terms of extracting the phase fraction of the tetragonal and orthorhombic phases, while Rietveld refinement has been applied to grazing incidence x-ray diffraction of thick (10 nm) Zr:HfO₂55 to determine the orthorhombic phase fraction, that methodology cannot be applied in the ultrathin regime, as the films are highly oriented, as opposed to fully polycrystalline (FIG. 8B), which is a requirement to apply Rietveld refinement.

### X-ray Absorption Spectroscopy.

Hard and soft synchrotron X-ray spectroscopy (FIG. 9C) was measured at beamline 4-ID-D of the Advanced Photon Source, Argonne National Laboratory and Beamline 4.0.2. of the Advanced Light Source, Lawrence Berkeley National Laboratory, respectively. Spectroscopy measurements were taken at the oxygen K-edge (520-550 eV), zirconium M3,2-edge (325-355 eV), hafnium M3-edge (2090-2150 eV), and zirconium L3,2-edge (2200-2350 eV). X-rays were incident at 20° off grazing. An X-ray absorption spectroscopy (XAS) (X-ray linear dichroism) was obtained from the average (difference) of horizontal and vertical linearly polarized X-rays. To eliminate systematic artifacts in the signal that drift with time, spectra measured at ALS were captured with the order of polarization rotation reversed (e.g., horizontal, vertical, vertical, and horizontal) in successive scans, in which an elliptically polarizing undulator tuned the polarization and photon energy of the synchrotron X-ray source. Spectra measured at Advanced Light Source were recorded under total electron yield mode from room temperature down to 100 K. Spectra measured at Advanced Photon Source were recorded under various modes: total electron yield, fluorescence yield, and reflectivity.

FIGS. 9A to 9F illustrate ferroic phase insights: proximity to temperature-dependent phase transition. FIG. 9C shows temperature-dependent XAS at the oxygen K-edge for a 2 nm HfO₂—ZrO₂—HfO₂ bare film demonstrating clearer spectroscopic signatures of the ferroelectric O-phase emerge slightly below room temperature.

Ferroic Phase Identification from Spectroscopy.

X-ray spectroscopy provides various signatures to distinguish the competing ferroelectric orthorhombic (Pca2₁) and antiferroelectric tetragonal (P4₂/nmc) phases. Simulated XAS spectra at the oxygen K-edge (FIG. 9D) for ZrO₂ in the various fluorite-structure polymorphs (orthorhombic Pca2₁ and tetragonal P4₂/nmc) were computed through the Materials Project open-source database for XAS spectrum. The T-phase (P4₂/nmc) nonpolar distortion (D₄_{ₕ}, fourfold prismatic symmetry) from regular tetrahedral (Ta, full tetrahedral symmetry) fluorite-structure symmetry does not split the degenerate e-bands (dₓ²_{-y}², d_{3z}²₋ᵣ²) as confirmed by experiment and the aforementioned XAS simulations. Meanwhile, the O-phase (Pca2₁) polar rhombic pyramidal distortion (C2v, twofold pyramidal symmetry) does split the e-manifold based on crystal field symmetry, providing a spectroscopic means to distinguish the T-phase and O-phase. The additional spectroscopic feature present between the main e-absorption and t2- absorption features due to orthorhombic symmetry-lowering distortion is illustrated by its crystal field diagram (FIG. 9B). This provides a spectroscopic fingerprint for phase identification beyond diffraction, which can often be ambiguous due to the nearly identical T-phase and O-phase lattice parameters. For the 2 nm HfO₂—ZrO₂—HfO₂ trilayer, the experimental O K-edge XAS spectra demonstrates tetrahedral and rhombic splitting features closely matching the polar O-phase (Pca2₁) emerge slightly below room temperature, indicative of the mixed tetragonal-orthorhombic to orthorhombic phase transition upon cooling. This temperature-dependent tetragonal-orthorhombic structural evolution is expected for fluorite-structure thin films and is consistent with temperature-dependent capacitance measurements (FIGS. 9E and 9F).

FIG. 9B shows crystal field splitting for fluorite-structure polymorphs; the symmetry-induced e-splitting provides a spectroscopic signature for the polar O-phase.

FIG. 9C shows hard and soft synchrotron X-ray spectroscopy measured at beamline 4-ID-D of the Advanced Photon Source.

FIG. 9D shows simulated oxygen K-edge XAS spectra for the respective O-phase and T-phase; the XAS provides spectroscopic signatures to distinguish between the O-phase and T-phase, which are difficult to resolve from GID.

FIG. 9E shows prototypical C-V behavior for mixed antiferroelectric-ferroelectric (shoulder-like features in addition to the characteristic butterfly-like shape) and ferroelectric films (just butterfly-like) in MIM capacitor structures.

FIG. 9F shows temperature-dependent C-V for thicker HfO₂—ZrO₂ multilayers of the same periodicity (in a MIM capacitor structure) demonstrating an evolution from mixed-ferroic to ferroelectric-like hysteresis upon cooling slightly below room temperature. Thinner HfO₂—ZrO₂ multilayers films suffer from leakage-limitations, preventing such hysteretic C-V measurements. The thicker HfO₂—ZrO₂ multilayers of the same periodicity-annealed at the same low-temperature condition to maintain the multilayer structure-demonstrate a similar mixed ferroic to ferroelectric phase transition slightly below room temperature as the thinner 2 nm multilayer (FIG. 9C).

### X-Ray Photoelectron Spectroscopy.

Angle-resolved photoelectron spectroscopy was performed using a Phi Versaprobe III at the Stanford Nano Shared Facilities (FIG. 6D). A monochromated aluminum source was used to give a photon energy of 1486.6 eV. Data were fit and analyzed using CasaXPS. Angle-dependent XPS at various incident grazing angles enabled depth-resolved composition analysis to help confirm the HfO₂—ZrO₂ multilayer structure.

### Dielectric Measurements

### Metal-Oxide-Semiconductor Capacitance.

Capacitance-voltage (C-V) measurements were performed using a commercial Semiconductor Device Analyzer (Agilent B1500) with a multi-frequency capacitance measuring unit. Nineteen-micron W tips (d.c.P-HTR 154-001, FormFactor) made electrical contact within a commercial probe station (Cascade Microtech); voltage was applied to the W top electrode, and the lightly doped Si bottom electrode was grounded. To eliminate contributions from series and parasitic resistances, frequency-dependent C-V measurements were performed. In particular, C-V data were analyzed at two frequencies (100-500 kHz regime) to allow for the extraction of accurate frequency-independent C-V via a three-element circuit model consisting of the capacitor and the parasitic series and parallel resistors. The frequency-independent capacitance is given by

$$C = \frac{{f}_{1}^{2} {C}_{1} ( 1 + {D}_{1}^{2} ) - {f}_{2}^{2} {C}_{2} ( 1 + {D}_{2}^{2} )}{{f}_{1}^{2} - {f}_{2}^{2}} , \qquad ( 1 )$$

where Cᵢ and Dᵢ refer to the measured capacitance in parallel mode (Cₚ-Rₚ) −cot θ, where θ is the phase. To maximize the accuracy of this method, it is important that the dissipation factors are small («1) at the frequencies chosen; therefore, high frequencies were selected.

### Permittivity Extraction

The permittivity of Al₂O₃ and HfO₂ dielectric layers was extracted from thickness-dependent MOS C-V measurements on lightly doped p substrates (FIGS. 10A to 10F). In the accumulation region of the MOS C-V measurements, the MOS capacitor can be modeled as three capacitors (Al₂O₃ or HfO₂ dielectric layer, SiO₂ interlayer, and Si space charge layer) in series using the following equation,

$$\frac{1}{C} = \frac{1}{{ϵ}_{0} {ϵ}_{H κ}} {r}_{H κ} + \frac{1}{{ϵ}_{0} {ϵ}_{{SiO}_{2}}} [ {t}_{S i {O}_{2}}^{phys} + {t}_{CL} \frac{{ϵ}_{{SiO}_{2}}}{{ϵ}_{Si}} ] , \qquad ( 2 )$$

where t_{Hκ} is the thickness of the high-κ (Al₂O₃ or HfO₂) layer, t_{SiO}_{₂}^{phys} is the physical SiO₂ thickness, and t_{CL} is the charge layer thickness in silicon. The physical SiO₂ thickness is constant across all of the thickness series (Al₂O₃ and HfO₂ single layers). Additionally, the capacitance values were extracted at various values of fixed charge (Q=−1 to −2 μC/cm²), which ensures that the charge-layer thickness is constant across all thicknesses and in the accumulation region. Therefore, from Equation 2, the inverse capacitance at a fixed charge as a function of film thickness should result in a line, and the permittivity can be extracted from the slope. This yielded extracted permittivities of 9 and 19 for the Al₂O₃ and HfO₂ thickness series, respectively, as expected for these systems. Note that for the HfO₂ thickness series, thicknesses of 6 nm and higher were used to ensure HfO₂ stabilizes in the dielectric monoclinic phase (κ˜18).

Similarly, the permittivity of the HfO₂—ZrO₂ heterostructures was extracted from thickness-dependent MIM C-V measurements (FIG. 2B). The inverse capacitance is a linear function of the film thickness, and the permittivity can be extracted from the slope.

### Electrical Interlayer Thickness Extraction.

The thickness of the SiO₂ interlayer was determined not only by TEM (FIG. 10A) but also electrically via C-V measurements of both dielectric HfO₂ and Al₂O₃ thickness series on SiO₂-buffered Si (FIG. 10F). From Equation 2, the inverse capacitance at a fixed charge as a function of dielectric thickness should result in a line, and the capacitance-equivalent thickness (CET) of the SiO₂ interlayer and Si charge layer can be extracted from the y-intercept. By extracting the CET at different charge values, the Q-V relation of the SiO₂ interlayer and Si charge layer can be calculated through the following equation,

$$V - {V}_{fb} = {\int }_{0}^{Q} \frac{{t}_{{SiO}_{2}}^{phys} + {t}_{CL \frac{{ϵ}_{{SiO}_{2}}}{{ϵ}_{S i}}}}{{ϵ}_{0} {ϵ}_{{SiO}_{2}}} dQ , \qquad ( 3 )$$

where V_{ƒb} is the flatband voltage (FIGS. 10B and 10D). To confirm this methodology, another method for determining the Q-V relation of the SiO₂ interlayer and Si charge layer was extracted from the Q-V relations of both the dielectric HfO₂ and Al₂O₃ thickness series. At a fixed charge, the corresponding voltage values of each thickness were fit to a line, and the y-intercept corresponds to the voltage value for the SiO₂ interlayer and Si charge layer Q-V relation. As expected, both methods lead to the same extracted Q-V relation (FIGS. 10C and 10E), corresponding to 8 Å EOT (FIG. 10F)-close to the SiO₂ physical thickness of 8.5 Å obtained via TEM (FIG. 10A)-based on simulated technology computer-aided design (TCAD) Q-V relations of different SiO₂ thicknesses on lightly doped Si. FIGS. 10A to 10F illustrate SiO₂ interlayer thickness. FIG. 10A illustrates zoomed-out (left) and zoomed-in (center) cross-sectional TEM images of HfO₂—ZrO₂ multilayer structure; and a physics SiO₂ thickness of 8.5 Å is extracted from a intensity line scan (right) taken from a vertical cut of the cross-sectional TEM image. Note that the intensity of the interface between SiO₂ and the Si substrate is determined based on the oxygen content and not purely the intensity linescan, due to their similar intensity.

FIGS. 10B and 10D show C-V measurements of HfO₂ and Al₂O₃ thickness series, respectively, in MOS capacitor structures (left), extracted inverse capacitance versus thickness at various values of charge (center), and extracted Q-V relation Si charge layer and SiO₂ interlayer (SiL) (right), which fits to technology computer-aided design simulations for 8.0 Å SiO₂; and the SiL Q-V relation was found by integrating the extracted capacitance equivalent thickness of Sil versus charge (right, inset). This electrical interlayer thickness (8.0 Å) is consistent with the physical thickness as determined by TEM (8.5 Å) .

FIGS. 10C and 10E show Q-V curves of HfO₂ and Al₂O₃ thickness series, respectively, obtained from integrating MOS C-V measurements (top left), extracted voltage vs. thickness at various values of charge (top right), and extracted Q-V relation of SiL (bottom center); and the SiL Q-V relation is consistent with the Q-V relation extracted from the C-V data (right, inset).

FIG. 10F shows the consistency in the SiL Q-V relation extracted from the C-V data from both the HfO₂ and Al₂O₃ thickness series, which fits to an SiO₂ interlayer thickness of 8.0 Å.

### Hysteretic C-V Measurements.

Capacitance-voltage (C-V) measurements on MIM capacitors were performed using a commercial Semiconductor Device Analyzer (Agilent B1500) with a multi-frequency capacitance measuring unit. Nineteen-micron W tips (d.c.P-HTR 154-001, FormFactor) made electrical contact within a commercial probe station (Cascade Microtech); voltage was applied to the W top electrode and the W bottom electrode was grounded.

### Electrical Characterization

### Benchmarking to HKMG Literature

In FIG. 4A, the leakage-effective oxide thickness (JG-EOT) scaling of negative capacitance multilayer gate stack benchmarked against reported high-κ metal gate (HKMG) literature includes references taken from interlayer-scavenged 2 nm HfO₂ (triangles, circles, squares), high-κ doped HfO₂ (diamonds), and SiO₂/poly-Si (negative sloped thin line)). In FIG. 4B, the normalized mobility versus EOT scaling of the negative capacitance multilayer gate stack benchmarked against reported HKMG literature includes references taken from interlayer-scavenged 2 nm HfO₂ (triangles, circles, squares, diamonds) and hybrid silicate-scavenged interlayer (area between positive sloped thin lines). In the FIG. 4B inset, the SiO₂ interlayer thickness versus EOT scaling scatter plot considers the 7.0 Å EOT HfO₂—ZrO₂—HfO₂ trilayer to HKMG references that employ interlayer scavenging to reduce EOT.

### Transistor Transfer and Output Characteristics.

Transistor I_{d}-V_{g} and I_{d}-V_{d} characterization of short-channel and long-channel transistors were performed using a commercial Semiconductor Device Analyzer (Agilent B1500). Nineteen-micron W tips (d.c.P-HTR 154-001, FormFactor) made electrical contact within a commercial probe station (Cascade Microtech); voltage was applied to the gate and drain contacts, while the source and Si substrate were grounded.

### Mobility Extraction.

The low-field transistor mobility is calculated based on the channel resistance (R_{ch}) and inversion sheet charge density (Qᵢₙᵥ), which are extracted respectively from transfer characteristics (I_{D}-V_{GS}) and from the gate-to-channel capacitance-voltage (C_{gc}-V_{GS}) measurements. Given the the device aspect ratio of channel length (L) and channel width (W), then

$${R}_{ch} ( {V}_{G S} ) = \frac{L}{W} \times \frac{1}{{μ}_{eff} ( {V}_{G S} ) {Q}_{i n v} ( {V}_{G S} )} . \qquad ( 4 )$$

First, the channel resistance is extracted at 50 mV drain-to-source bias (V_{DA}) by subtracting the parasitic resistance (Rₚ) from the measured drain-to-source resistance (R_{DS}).

$${R}_{D S} ( {V}_{G S} ) = \frac{{V}_{DS}}{{I}_{D} ( {V}_{G S} )} = {R}_{c h} ( {V}_{G S} ) + {R}_{p} \qquad ( 5 )$$

where Rₚ is ascribed to the resistance of the source and the drain contacts and the n+extension regions that are extrinsic to the channel region. When the overdrive voltage (Vₒᵥ=V_{GS}−Vₜ, where Vₜ is the threshold voltage) is sufficiently large, R_{ch} is known to be inversely proportional to Vₒᵥ according to Equation 4. Therefore, Rₚ can be extracted using a linear extrapolation of the R_{DS}−1/Vₒᵥ relationship (FIG. 11D), which is derived from the I_{D}V_{GS} from which the threshold voltage (Vₜ) can be characterized with the maximum-gₘ method. Secondly, the C_{gc}-V_{GS} of a large (W=L=50 μm) device (FIG. 11A) is integrated and normalized to the channel area (A=2500 μm²) to estimate the inversion charge.

$${Q}_{i n v} ( {V}_{G S} ) \approx {\int }_{- ∞}^{{V}_{G S}} \frac{{C}_{gc} ( {V}_{gs} )}{A} d {v}_{gs} . \qquad ( 6 )$$

The large device dimensions minimizes the parasitic capacitance contribution to ensure C_{gc} is representative of the inversion electron responses. Finally, the foregoing characterizations are combined to obtain the effective mobility using Equation 4 (FIG. 11E).

FIGS. 11A to 11G illustrate mobility extraction. FIG. 11A shows split C-V curves obtained for multilayer HfO₂—ZrO₂ gate stacks (repeated 1 and 3 times, that is, HZH×1 and HZH×3) and 60 Å HfO₂ dielectric control (Hf-60) from L_{G}=50 μm bulk transistors at 10 KHz. These C-V curves were fit to EOT simulations of 7.5 Å, 10.6 Å, and 18 Å for HZH×1, HZH×3, and Hf-60, respectively. From the off-state accumulation C-V, a doping level of Na=2×10¹⁷ cm⁻³ was extracted; and from the slope of the inversion C-V, the interface trap density was found to be Dᵢₜ=3×10¹² ev⁻¹ cm⁻².

FIGS. 11B and 11C show I_{D}-V_{G} and gₘ-V_{G} (transfer characteristics, respectively, for L_{G}=1 μm bulk transistors at V_{DS}=50 mV for multiple devices per sample.

FIG. 11D shows a series resistance extraction from 1/Vₒᵥ method for Vₒᵥ=V_{gs}−Vₜ=0.3 V to 0.5 V for L_{G}=1 μm. The threshold voltage was extracted from the maximum gₘ method.

FIG. 11E shows extracted mobility as a function of inversion

sheet charge density; the effective mobility was taken to be the average maximum mobility across all measured devices.

FIGS. 11F and 11G show transfer I_{D}-V_{G} and gₘ data, respectively, fit to a constant mobility model based on the extracted effectively mobility in FIG. 11E. All data shown are taken for LG=1 μm bulk transistors, and a summary of the EOT-mobility trend from the various samples is provided in FIGS. 4A to 4F.

### Transconductance Extraction.

The measured transconductance (gₘ=∂I_{D}/∂V_{GS}) and the output conductance (g_{ds}=∂I_{D}/∂V_{DS}) are affected by the series resistance on the source (R_{S}) and the drain sides (R_{D}), as they reduce the voltage drops on the channel region.

V_{GSi}=V_{GS}−I_{D}Rₛ (7)

V_{DSi}=V_{DS}−I_{D}(Rₛ+R_{D}), (8)

where V_{GSi} and V_{DSi} are the gate-to-source and the drain-to-source voltages intrinsic to the channel, respectively. R_{S}≈R_{D}≈Rₚ/2 because the transistor is symmetric.

Rₚ can be extracted from the R_{DS}−1/Vₒᵥ relationships as discussed in the “Mobility extraction” section (FIG. 12B). Besides, devices with different gate length (L_{g}) series are fabricated on the SOI wafer, which enables another extraction method with R_{SD}−L_{g} relations. At low V_{D} and a given Vₒᵥ, Qᵢₙᵥ and μ_{eff} are unchanged across different gate lengths (L_{g}) if the short-channel effect is not significant, making R_{ch} proportional to the channel length. Such conditions are confirmed by the consistency of Vₜ across measured L_{g} (FIG. 12A). Therefore, the L_{g} offset and the Rp can be found at the intersect of the linear relations of the R_{SD}-L_{g} with different Vₒᵥ (FIG. 12C). The two Rₚ extraction methods yield consistent results.

FIGS. 12A to 12E illustrate transconductance extraction. FIG. 12A shows threshold voltage extraction by linear extrapolation for various channel lengths; all channel lengths give nearly constant V_{T}(˜0.42 V), satisfying the assumption for the line resistance method.

FIG. 12B shows source/drain series resistance extracted using the 1/Vₒᵥ method; by performing a linear interpolation of the total resistance for Vₒᵥ=0.5 V to 0.6 V, the extracted series resistance is ˜500 Ω-μm.

FIG. 12C shows source/drain series resistance extracted using the line resistance method; the trend is considered down to L_{G}=90 nm, which intersects at ˜500-600 Ω-μm and which is consistent with the 1/Vₒᵥ method, with an L_{G} offset of ˜50 nm.

The following equation is solved to extract the intrinsic gₘᵢ=∂I_{D}/∂V_{GSi} and g_{dsi}=∂I_{D}/∂V_{DSi} without the degradation due to R_{S} and R_{D}.

$$( \begin{matrix}1 - {g}_{m} {R}_{S} & - {g}_{m} ( {R}_{S} + {R}_{D} ) \\ - {g}_{ds} {R}_{S} & 1 - {g}_{ds} ( {R}_{S} + {R}_{D} )\end{matrix} ) ( \begin{matrix}{g}_{m i} \\ {g}_{dsi}\end{matrix} ) = ( \begin{matrix}{g}_{m} \\ {g}_{ds}\end{matrix} ) , \qquad ( 9 )$$

where gₘ and g_{ds} are measured, and R_{S}≈R_{D}≈Rₚ/2 from the foregoing discussed characterizations. Using this methodology, the intrinsic gₘᵢ and intrinsic g_{dsi} are extracted (FIG. 4F; FIGS. 12D and 12E).

FIGS. 12D and 12E show measured (left) and extracted (right) transconductance and showing output conductance, respectively, versus VG for V_{DS}=0.9 V to 1.1 V, assuming Rₛ=R_{d}=250 Ω-μm for L_{G}=90 nm. The de-embedding of intrinsic gₘ and g_{ds} from extrinsic Gₘ and G_{ds} is described in the methods section. All data shown were measured on SOI short-channel transistors integrating the 2 nm HfO₂—ZrO₂—HfO₂ ferroic gate stack.

### Radio Frequency Measurements.

Scattering-parameters (S parameters) for L_{G}=1 μm bulk transistors (henceforth referred to as the device under test, DUT) at various DC biases as well as open and short structures (FIG. 13A) are measured using a Keysight E8361C Network Analyzer in conjunction with a Keysight 4155C Semiconductor Parameter Analyzer. The devices were measured using low contact resistance Infinity Series probes. To calibrate the measurement setup, a line-reflect-reflect-match calibration was performed with a Cascade Microtech Impedance Standard. Following calibration, S-parameters were measured for each of the DUT, open, and short structures. These measured S-parameters were converted to admittance parameters (Y-parameters), Y_{DUT}, Yₒₚₑₙ, and Yₛₕₒᵣₜ. To remove the effects of parasitic shunt parasitic pad capacitance and series pad resistance and inductance of the DUT, the following de-embedding process was followed. First, to decouple the effect of shunt parasitic capacitances, the Y parameters of the open structure (Yₒₚₑₙ) are subtracted from the Y parameters of the DUT and short structure and then are converted to impedance parameters (Z parameters):

Z₁=(Y_{DUT}−Yₒₚₑₙ)⁻¹ (10)

Z₂=(Yₛₕₒᵣₜ−Yₒₚₑₙ)⁻¹ (11)

Next, to decouple the effect of series pad resistance and inductance of DUT, Z₂ is subtracted from Z₁, and the resulting difference is converted back to admittance parameters, Y_{corr}:

Y_{corr}=(Z₁−Z₂)⁻¹ (12)

Y_{corr} represents the de-embedded admittance parameters of the DUT. This de-embedding procedure is schematically represented in FIG. 13A.

FIGS. 13A to 13C illustrate RF device characterization. FIG. 13A is a diagram of a de-embedding procedure for extracting corrected admittance parameters (Y_{corr}) by decoupling parasitic shunt capacitance and series resistance and inductance by measuring scattering parameters for the device under test (DUT) as well as open and short structures.

To extract the total gate capacitance (C_{gg}) and transconductance (gₘ) from the de-embedded admittance parameters, a small-signal model of the transistor was assumed (FIG. 13B). Under this small-signal model, the Y-parameters can be written in terms model parameters and frequency (assuming Rₛ=R_{d}=0, C_{gg}=C_{gs}+C_{gd}, and 4π²C_{gg}²R_{g}²ƒ²<<1).

Y₁₁=4π²C_{gg}²R_{g}ƒ²+2πƒC_{gg}j (13)

Y₁₂=−4π²C_{gd}C_{gg}R_{g}ƒ²−2πƒC_{gd}j (14)

Y₂₁=gₘ−4π²C_{gd}C_{gg}R_{g}ƒ²+2πƒ(C_{gd}+gₘR_{g}C_{gg})j (15)

Y₂₂=g_{ds}+4π²C_{gd}R_{g}(C_{gd}+C_{gg}gₘR_{g})ƒ²+2πƒ(C_{ds}+C_{gd}+C_{gd}gₘR_{g})j. (16)

The transconductance (gₘ) can therefore be extracted at a fixed DC bias via the following relation (FIG. 4C; FIG. 12C).

gₘ=Re(Y₂₁)|_{ƒ}_{²}₌₀ (17)

FIG. 13B shows a small-signal model for a transistor used to extract transconductance (gₘ) and total gate capacitance (C_{gg}=C_{gs}+C_{gd}).

FIG. 13C shows de-embedded

$$\frac{R e [ {Y}_{21} ]}{2 π f}$$

(open circles) as a function of squared frequency at different DC V_{gs} bias points extrapolated to the zero frequency limit (dotted lines) to extract the RF gm. All data shown were extracted from bulk transistors (L_{G}=1 μm) integrating the 2 nm HfO2—ZrO₂—HfO₂ ferroic gate stack.

### Charge Boost Measurements.

Pulsed charge-voltage measurements (FIGS. 14A to 14F) were conducted on p-Si/SiO₂/HfO₂—ZrO₂ (2 nm)/TiN/W capacitor structures to extract the energy landscape of the ferroic HfO₂—ZrO₂ heterostructure. The capacitor structures were connected to an Agilent 81150A Pulse Function Arbitrary Noise Generator, and the current and voltage were measured through an InfiniiVision DSOX3024A oscilloscope with a 50 Ω and 1 MΩ input impedance, respectively. Short voltage pulses (500 ns) with increasing amplitudes were applied to the capacitor (FIG. 14C). From the integration of the measured discharging current, a charge vs. voltage relationship was extracted (FIG. 14D). The voltage was calculated by max(V−IR), where V is the applied voltage pulse, I is the measured current, and R is a combination of the oscilloscope resistance (50 Ω) and parasitic resistances associated with the setup and lightly doped substrate (220 Ω). Fast voltage pulses were applied in order to minimize charge injection into the ferroelectric-dielectric interface, which could mask the observation of the negative capacitance regime. Additionally, short voltage pulses help prevent electrical breakdown of the SiO₂ layer. To determine the P-E_{F} relation of the 2 nm HfO₂—ZrO₂ heterostructure, the electric field across the ferroic HfO₂—ZrO₂ heterostructure was calculated by subtracting the voltage across the series capacitance of the SiO₂ interlayer and Si charge layer (V_{D}) at a fixed charge value,

$$E = \frac{1}{t} ( V - {V}_{D} ) , \qquad ( 18 )$$

where t is the thickness of the HfO₂—ZrO₂ heterostructure. The Q-V relation of the series capacitance of the SiO₂ interlayer and Si charge layer was determined via thickness-dependent C-V measurements of Al₂O₃ and HfO₂ (FIGS. 10A to 10F; Electrical interlayer thickness extraction), which corresponded to 8 Å SiO₂ on lightly doped Si. The charge boost due to negative capacitance was calculated by integrating the difference between the Q-V relations of the 2 nm HfO₂—ZrO₂ heterostructure and the series combination of the SiO₂ interlayer and the Si charge layer (FIG. 14E).

FIGS. 14A to 14F illustrate capacitance and charge enhancement. FIG. 14C shows the applied voltage pulse (top), the measured current response (center), and the integrated charge (bottom) as a function of time for 2 nm HfO₂—ZrO₂—HfO₂ trilayer in MOS capacitors.

FIG. 14D shows the maximum charge Qₘₐₓ, the residual charge Qᵣₑₛ, and their difference, Qᵣₑᵥ, derived from the charge vs. time curve for each of the voltage pulses.

FIG. 14E shows the reversible charge of the MOS layer (top) compared with the extracted charge of the Si charge layer plus SiO₂ interlayer (SiL) derived electrically (see FIG. 7F). The charge boost (bottom) present in the total MOS structure (SiL plus HZH capacitors) compared with just the Sil is a signature of negative capacitance, as previously demonstrated in metal-ferroelectric-insulator-metal structures.

FIG. 14A shows a MOS of the 20 Å HfO₂—ZrO₂—HfO₂ mixed ferroic trilayer sample on lightly doped Si (10¹⁵ cm⁻³) considered for the following accumulation C-V and pulsed I-V measurements.

FIG. 14B shows accumulation C-V curves for the 2 nm HfO₂—ZrO₂—HfO₂ trilayer grown on sub-nanometer SiO₂ fit to effective oxide thickness (EOT) simulations, and the inset shows externally verified MOS accumulation C-V of the same trilayer stack, demonstrating 6.5 Å EOT. The 2 nm trilayer on top of SiO₂ demonstrates lower EOT than the thickness of SiO₂ interlayer alone, carefully extracted via physical (8.5 Å) and electrical (8.0 Å) methodologies (see FIGS. 10A to 10F), providing evidence of capacitance enhancement.

FIG. 14F is a scatter plot of reported ferroelectric-dielectric systems demonstrating negative capacitance at the capacitor level via capacitance (C-V measurements) or charge (pulsed I-V measurements) enhancement. The plot considers fluorite-structure bilayers (red), perovskite-structure bilayers (blue, BL), and perovskite-structure superlattices (blue, SL). Employing the sub-nanometer SiO₂ interlayer and 2 nm HfO₂—ZrO₂ multilayer on silicon (black, star) as disclosed provides the most scaled demonstration of negative capacitance, as supported by enhanced capacitance from C-V measurements (FIG. 14B) and amplified charge from pulsed I-V measurements (FIG. 14E) relative to the SiO₂ dielectric interlayer.

### Modeling

### Landau Phenomenology of Antiferroelectric-Ferroelectric System.

The qualitative energy landscape for a mixed ferroelectric-antiferroelectric material (FIG. 1A) was calculated by assuming a series combination of antiferroelectric and ferroelectric layers connected to a voltage source Vs. The energy landscape potentials were calculated via the Landau-Ginzburg-Devonshire formalism (without strain coupling):

U_{FE}=(α_{FE}P²+β_{FE}P⁴+γ_{FE}P⁶−E_{FE}P)t_{FE} (19)

U_{AFE}=(α_{AFE}(P_{α}²+P_{b}²)+δ_{AFE}P_{α}P_{b}=β_{AFE}(P_{α}⁴+P_{b}⁴)+γ_{AFE}(P_{α}⁶+P_{b}⁶)−E_{AFE}(P_{α}+P_{b}))t_{AFE} (20)

For the antiferroelectric layer, the energy landscape assumes two sublattices (Pₐ, P_{b}) with spontaneous, antiparallel dipoles. To express the AFE energy landscape in terms of total polarization, a change of variables was performed (P=Pₐ+P_{b}, A=Pₐ−P_{b}). The antiferroelectric profile therefore becomes,

$${U}_{AFE} = {t}_{AFE} ( \frac{1}{2} {α}_{AFE , p} {P}^{2} + \frac{1}{2} {α}_{AFE , n} {A}^{2} + \frac{{β}_{AFE}}{8} ( {P}^{4} + 6 {A}^{2} {P}^{2} + {A}^{4} ) + \frac{{γ}_{AFE}}{32} ( {P}^{6} + {A}^{6} + 15 {P}^{2} {A}^{2} ( {A}^{2} + {P}^{2} ) ) - {E}_{AFE} P ) \qquad ( 21 )$$

The system is also constrained by electrical boundary conditions at the antiferroelectric/ferroelectric interface ϵ₀E_{AFE}+P_{AFE}=ϵ₀E_{FE}+P_{FE} and that the voltage across both layers must sum up to V_{f}(V_{g}=E_{FE}t_{FE}+E_{AFE}t_{AFE}). With these constraints, the combined energy profile is given by

$${U}_{AFE + FE} = {T}_{AFE} ( \text{} \frac{1}{2} {α}_{AFE , p} {P}_{AFE}^{2} + \frac{1}{2} {α}_{AFE , n} {A}_{AFE}^{2} + \frac{{β}_{AFE}}{8} ( {P}_{AFE}^{4} + 6 {A}_{AFE}^{2} {P}_{AFE}^{2} + {A}_{AFE}^{4} ) + \frac{{γ}_{AFE}}{32} ( {P}_{AFE}^{6} + {A}_{AFE}^{6} + 15 {P}_{AFE}^{2} {A}_{AFE}^{2} ( {A}_{AFE}^{2} + {P}_{AFE}^{2} ) ) ) + ( {α}_{FE} {P}_{FE}^{2} + {β}_{FE} {P}_{FE}^{4} + {γ}_{FE} {P}_{FE}^{6} ) {t}_{FE} - {V}_{g} \frac{{P}_{FE} {t}_{FE} + {P}_{AFE} {t}_{AFE}}{{t}_{FE} + {t}_{AFE}} + \frac{{t}_{AFE} {{t}_{FE} ( {P}_{AFE} - {P}_{FE} )}^{2}}{{ϵ}_{0} ( {t}_{FE} + {t}_{AFE} )} \qquad ( 22 )$$

To further simplify this expression, note that the last term represents the electrostatic energy arising from polarization mismatch at the AFE-FE interface. In general, such mismatch is quite costly, resulting in nearly uniform polarization across all layers. Therefore, the approximation (P_{AFE}=P_{FE}=P) is applied, which sets the last term to 0. Furthermore, to express U as just a function of P, another constraint can be generated by noting that in equilibrium, ∇U_{A}=0, resulting in the constraint,

$$0 = A ( \frac{{β}_{AFE}}{2} + \frac{{γ}_{AFE}}{32} ( 6 {A}^{2} + 60 {p}^{2} ) ) = - {α}_{{AFE}_{n}} - \frac{3}{2} {β}_{AFE} {P}^{2} - \frac{15}{16} {γ}_{AFE} {P}^{4} \qquad ( 23 )$$

This constraint allows for the determination of A for any value of P, which allows one to determine U as a function of P (FIG. 1A).

Technology computer-aided design simulations. The measured C-V curves are calibrated to Sentuarus Technology computer-aided design simulations device simulator, which solves the electrostatics, electron and hole transports, and the quantum confinement effect self-consistently. The MOS capacitors with 1×10¹⁵ cm⁻³ p-type substrate doping and L=50 μm planar MOSFETs with 2×10¹⁷ cm⁻³ p-type substrate doping are simulated with finite-element method. The EOT and the metal work function (φm) are the only two parameters that are fit to the MOS capacitor measurement results, yet the slope of the accumulation capacitance can be successfully captured by the model (FIG. 2F; FIGS. 10A to 10F). Similarly, both components (gate-to-channel and gate-to-body) of the MOSFET split C-V are captured by the TCAD model with appropriate EOT, φm, and an Si/SiO₂ interface state density of 2×10¹² cm⁻²eV⁻¹ (FIG. 11A).

Atomic-Scale HfO₂—ZrO₂ Mixed-Ferroic Heterostructure

### Thickness Limits and Atomic-Scale Heterostructures.

Recent perspectives on HfO₂-based ferroelectricity for device applications posed the technological challenges stemming from thickness limit concerns of HfO₂-based ferroelectricity, and thereby, negative capacitance. The use of short-period superlattices, that is, nanolaminates, is common in the high-κ field to enhance permittivity; in particular, rutile-structure titanium oxide (TiO₂) is often paired with fluorite-structure HfO₂ and/or ZrO₂ in dynamic random-access memory (DRAM) capacitors. Recently, fluorite-structure nanolaminates were employed to tune the ferroelectric behavior of HfO₂—ZrO₂ films. However, all previous works have studied nanolaminates with thick periodicity, going as thin as 10 ALD cycles (˜1.1 nm) per superlattice sub-layer. The method of the present disclosure scales down to a much thinner thickness limit while still maintaining physical separation of the individual layers (FIGS. 6A to 6D). The reasoning behind using a short-period superlattice structure to scale down the ferroic behavior of HfO₂—ZrO₂ rather than simply thinning down a solid solution stems from the notorious thickness-dependent ferroelectric behavior in Zr:HfO₂ at fixed composition. In the present disclosure, the use of nanolaminated structures can help provide thickness-independent scaling of ferroic order, as has been previously demonstrated to overcome the upper thickness limit of HfO₂-based ferroelectricity. The persistence of high capacitance for these 2 nm films is notable considering other high-κ dielectric systems suffer from significant permittivity degradation in the thin film (sub-10 nm) regime, particularly TiO₂-based and strontium titanium oxide (SrTiO₃)-based oxides. Sustaining the mixed ferroic order underlying negative capacitance to the 2 nm regime is extremely relevant for advanced technology nodes, which budget only ˜2 nm for the oxide layer.

### Iso-Structural Polycrystalline Multilayer.

Previous attempts to heterostructure ferroelectric Zr: HfO₂ with dielectric Al₂O₃ failed to demonstrate capacitance enhancement, which was attributed to the fixed charges at the ferroelectric-dielectric interface. These charges can screen the ferroelectric polarization, pushing the stable point of the energy well to one of the minimum points, and thereby preventing stabilization of negative capacitance regime via depolarization fields from the dielectric. In the present disclosure the use of iso-structural HfO₂—ZrO₂ to serve as both the nonpolar (antiferroelectric) and polar (ferroelectric) layers, and leveraging the high (low) onset crystallization temperature of HfO₂ (ZrO₂) on Si, enables interfaces with diminished defects, allowing for the polar layer to experience the depolarization fields and stabilize in the “forbidden” negative charge regime. Regarding the polycrystalline nature of the ultrathin multilayers, it has been experimentally and theoretically established that negative capacitance can be stabilized in the presence of ferroelectric domains.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A gate stack (24) comprising:
an oxide layer (26) disposed over a semiconductor substrate (12); and
a periodic sequence of (HfO₂—ZrO₂)×N material layers (28) disposed over the oxide layer (26), wherein N is a natural counting number.

2. The gate stack (24) of claim 1 wherein the oxide layer (26) comprises silicon dioxide.

3. The gate stack (24) of claim 2 wherein the oxide layer (26) is between 8 Å and 8.5 Å in thickness.

4. The gate stack (24) of claim 2 wherein the oxide layer (26) has an effective thickness between 5.5 Å and 6.5 Å.

5. The gate stack (24) of claim 1 further comprising a metal layer disposed over the periodic sequence of (HfO₂—ZrO₂)×N material layers (28).

6. The gate stack (24) of claim 5 further comprising the metal layer disposed over the oxide layer (26) in a metal-oxide-metal capacitor configuration.

7. A method of fabricating a gate stack (24) comprising:
disposing an oxide layer (26) over a semiconductor substrate (12); and
disposing a periodic sequence of (HfO₂—ZrO₂)×N material layers (28) over the oxide layer (26), wherein N is a natural counting number.

8. The method of fabricating the gate stack (24) of claim 7 wherein disposing the oxide layer (26) over the semiconductor substrate (12) is achieved through atomic layer deposition.

9. The method of fabricating the gate stack (24) claim 8 wherein disposing the periodic sequence of (HfO₂—ZrO₂)×N material layers (28) over the oxide layer (26) is achieved through atomic layer deposition.

10. The method of fabricating the gate stack (24) of claim 6 wherein the oxide layer (26) comprises silicon dioxide.

11. The method of fabricating the gate stack (24) of claim 10 wherein the oxide layer (26) is between 8 Å and 8.5 Å in thickness.

12. The method of fabricating the gate stack (24) of claim 10 wherein the oxide layer (26) has an effective thickness between 5.5 Å and 6.5 Å.

13. The method of fabricating the gate stack (24) of claim 6 further comprising disposing the metal layer over the periodic sequence of (HfO₂—ZrO₂)×N material layers (28).

14. A semiconductor device (10) comprising:
a semiconductor substrate (12) having a source region (14), a channel region (16) spaced from the source region (14), and a drain region (18) spaced from both the source region (14) and channel region (16);
a source contact (20) disposed over the source region (14);
a drain contact (22) disposed over the drain region (18); and
a gate stack (24) comprising:
an oxide layer (26) disposed over the channel region (16);
a periodic sequence of (HfO₂—ZrO₂)×N material layers (28) disposed over the oxide layer (26), wherein N is a natural counting number; and
a gate contact (30) disposed over the periodic sequence of (HfO₂—ZrO₂)×N material layers (28).

15. The semiconductor device (10) of claim 14 wherein the semiconductor substrate (12) comprises silicon.

16. The semiconductor device (10) of claim 14 wherein the oxide layer (26) comprises silicon dioxide.

17. The semiconductor device (10) of claim 16 wherein the oxide layer is between 8 Å and 8.5 Å in thickness.

18. The semiconductor device (10) of claim 16 wherein the oxide layer has an effective thickness between 5.5 Å and 6.5 Å.

19. The semiconductor device (10) of claim 14 wherein the source contact (20), the drain contact (22), and the gate contact (30) comprise metal.

20. The semiconductor device (10) of claim 14 having an intrinsic transconductance of between 1.7 μS/μm and 1.8 μS/μm.
